(19) United States
(12) Patent Application Publication
(10) Pub. No.: US 2025/0254855 A1
(43) Pub. Date: Aug. 7, 2025

(54) SEMICONDUCTOR MEMORY DEVICE

(71) Applicant: Samsung Electronics Co., Ltd., Suwon-si (KR)

(72) Inventors: Sung Nam Lyu, Suwon-si (KR); Eun Mi Kim, Suwon-si (KR); Hyo Jung Noh, Suwon-si (KR); Na Young Lee, Suwon-si (KR); Eul Ji Jeong, Suwon-si (KR)

(21) Appl. No.: 18/830,776

(22) Filed: Sep. 11, 2024

(30) Foreign Application Priority Data
Feb. 5, 2024 (KR) 10-2024-0017316

(51) Int. Cl. H10B 12/00

(52) U.S. Cl. CPC H10B 12/315; H10B 12/05; H10B 12/482; H10B 12/50

(57) ABSTRACT

A semiconductor memory device includes a bit line that extends in a first direction and is on a substrate, an active pattern on the bit line, a word line that is on the first side wall of the active pattern, and a data storage pattern that is on the active pattern, where the word line includes a first line pattern including a plurality of first conductive material crystals, where a direction in which a crystal lattice of each of the plurality of first conductive material crystals extends is substantially the same as the second direction, and at least one of the first surface of the word line or the second surface of the word line comprises at least one of the plurality of first conductive material crystals.

### CROSS-REFERENCE TO RELATED APPLICATION

This application claims priority from Korean Patent Application No. 10-2024-0017316 filed on Feb. 5, 2024 in the Korean Intellectual Property Office and all the benefits accruing therefrom under 35 U.S.C. 119, the contents of which in its entirety are herein incorporated by reference.

### TECHNICAL FIELD

The present disclosure relates to a semiconductor memory device, and more specifically, to a semiconductor memory device including a vertical channel transistor (VCT).

### BACKGROUND

There is a need to increase the degree of integration of semiconductor memory devices to satisfy desired performance characteristics and low prices desired by consumers. In the case of the semiconductor memory device, because the degree of integration is a factor in determining the price of a product, an increased degree of integration is particularly desired.

In the case of a two-dimensional or planar semiconductor memory device, the degree of integration thereof may be determined by an area occupied by unit memory cells, and is therefore greatly affected by the level of fine pattern forming technology. However, since expensive apparatuses may be used to miniaturize the pattern, the degree of integration of the two-dimensional semiconductor memory device is increasing, but is still limited. Accordingly, semiconductor memory devices that include vertical channel transistors whose channels extend in a vertical direction have been proposed.

### SUMMARY

Aspects of the present disclosure provide a semiconductor memory device having improved degree of integration and electrical characteristics.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some aspects of the present disclosure, there is provided a semiconductor memory device comprising a bit line that extends in a first direction and is on a substrate, an active pattern on the bit line, where the active pattern includes a first side wall and a second side wall that are opposite to each other in the first direction, where the active pattern includes a first surface and a second surface that are opposite to each other in a second direction that is perpendicular to the first direction, and where the first surface of the active pattern is electrically connected to the bit line, a word line that is on the first side wall of the active pattern and extends in a third direction that intersects the first direction, and a data storage pattern that is on the active pattern and is electrically connected to the second surface of the active pattern, where the word line includes a first surface and a second surface that are opposite to each other in the second direction, where the word line includes a first line pattern including a plurality of first conductive material crystals, a direction in which a crystal lattice of each of the plurality of first conductive material crystals extends is substantially the same as the second direction, and where at least one of the first surface of the word line or the second surface of the word line is defined by at least one of the plurality of first conductive material crystals.

According to some aspects of the present disclosure, there is provided a semiconductor memory device comprising a bit line that extends in a first direction and is on a substrate, a first active pattern on the bit line, a second active pattern that is on the bit line and spaced apart from the first active pattern in the first direction, a first word line that is between the first active pattern and the second active pattern and extends in a second direction that intersects the first direction, a second word line that is between the first active pattern and the second active pattern, extends in the second direction, and is spaced apart from the first word line in the first direction, a gate separation pattern that is on the bit line and includes a horizontal portion and a protruding portion, where the horizontal portion of the gate separation pattern is between the first word line and the bit line and between the second word line and the bit line, where the protruding portion of the gate separation pattern is between the first word line and the second word line, and where a width of the horizontal portion of the gate separation pattern in the first direction is greater than a width of the protruding portion of the gate separation pattern in the first direction, and a data storage pattern that is electrically connected to the first active pattern and the second active pattern, where the first word line includes a first plurality of conductive material crystals and the second word line each includes a second plurality of conductive material crystals, where the first plurality of conductive material crystals includes a first conductive material crystal, and where a height of the first conductive material crystal in a third direction that is perpendicular to the first direction and the second direction is equal to a height of the first word line in the third direction.

According to some aspects of the present disclosure, there is provided a semiconductor memory device comprising a peri-gate structure on a substrate, a bit line that extends in a first direction and is on the peri-gate structure, a shielding conductive pattern that is on the peri-gate structure and includes a plurality of shielding conductive line patterns that extend in the first direction and are adjacent to the bit line, a first word line that is on the bit line and the shielding conductive pattern and extends in a second direction that intersects the first direction, a second word line that is on the bit line and the shielding conductive pattern, extends in the second direction, and is spaced apart from the first word line in the first direction, a back gate electrode that is between the first word line and the second word line and extends in the second direction, a first active pattern that is on the bit line and is between the first word line and the back gate electrode, a second active pattern that is on the bit line and is between the first word line and the back gate electrode, and a data storage pattern that is electrically connected to the first active pattern and the second active pattern, where the first word line and the second word line each comprise a plurality of conductive material crystals that each have a crystal lattice that extends in a direction that is substantially the same as a third direction that is perpendicular to the first direction and the second direction, where the first word line includes a first surface and a second surface that are opposite to each other in the third direction, where the second word line includes a first surface and a second surface that are opposite to each other in the third direction, where a first set of the plurality of conductive material crystals comprise the first surface of the first word line and the second surface of the first word line, and where a second set of the plurality of conductive material crystals define the first surface of the second word line and the second surface of the second word line.

### BRIEF DESCRIPTION OF THE DRAWINGS

FIG. 1 is a layout diagram for explaining a semiconductor memory device according to some embodiments.

FIG. 2 is a cross-sectional view taken along lines A-A and B-B of FIG. 1.

FIG. 3 is a cross-sectional view taken along lines C-C and D-D of FIG. 1.

FIGS. 4 and 5 are enlarged views of a portion P of FIG. 2.

FIG. 6 is a diagram schematically showing a shape of a crystal grain of a cross section taken by cutting a word line of FIG. 4 in a first direction.

FIG. 7 is a diagram schematically showing a shape of the crystal grain of a cross section taken by cutting the word line of FIG. 4 in a second direction.

FIGS. 8, 9, 10, and 11 are diagrams for explaining a semiconductor memory device according to some embodiments.

FIGS. 12 and 13 are diagrams for explaining a semiconductor memory device according to some embodiments.

FIGS. 14 and 15 are diagrams for explaining a semiconductor memory device according to some embodiments.

FIGS. 16, 17, 18, and 19 are diagrams for explaining a semiconductor memory device according to some embodiments, respectively.

FIGS. 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, and 53 are diagrams for explaining a method for fabricating a semiconductor memory device according to some embodiments.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

Hereinafter, example embodiments will be explained in detail with reference to the accompanying drawings.

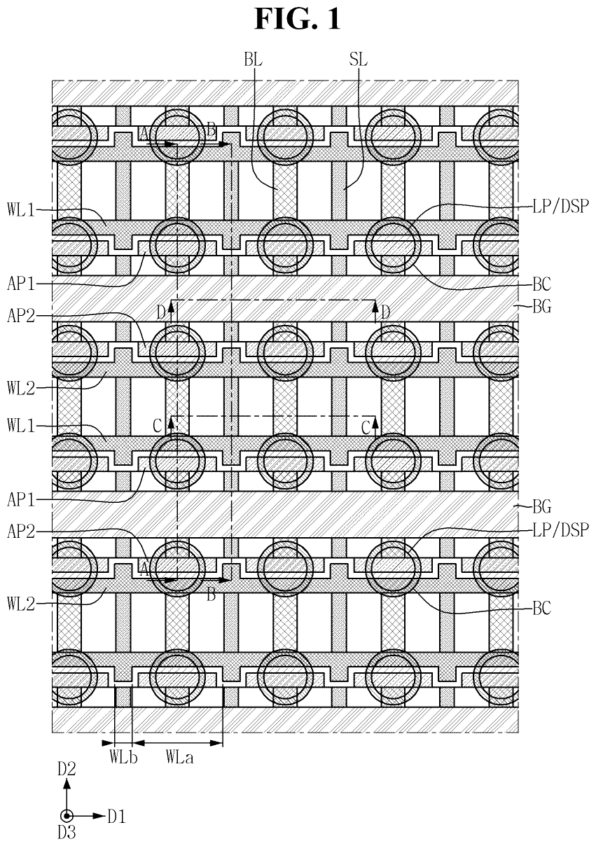

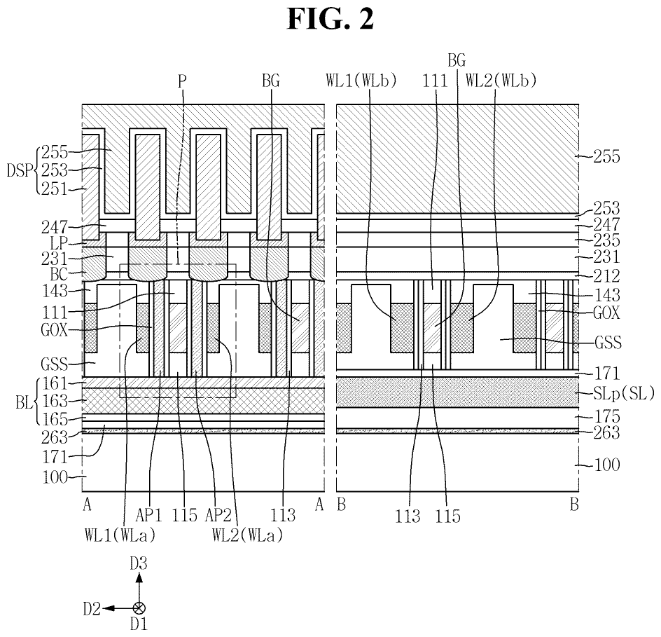

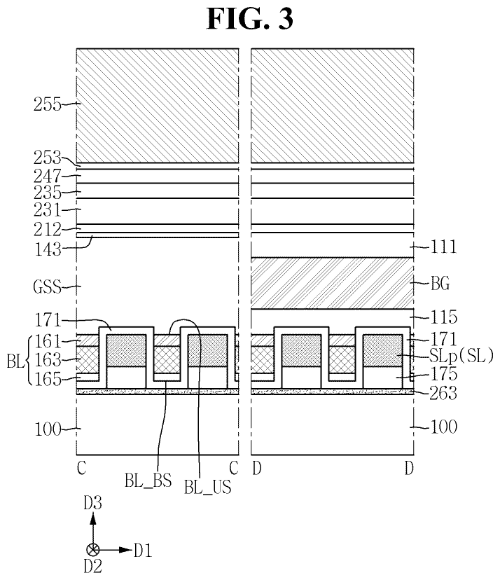

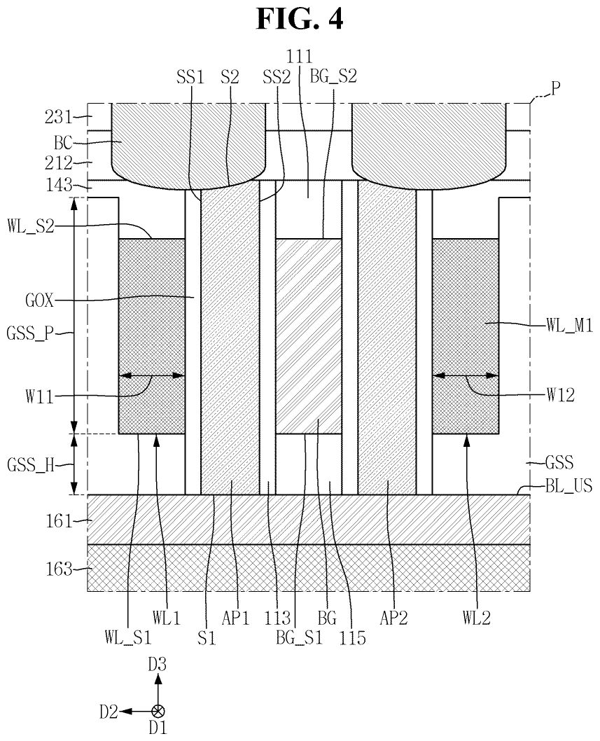

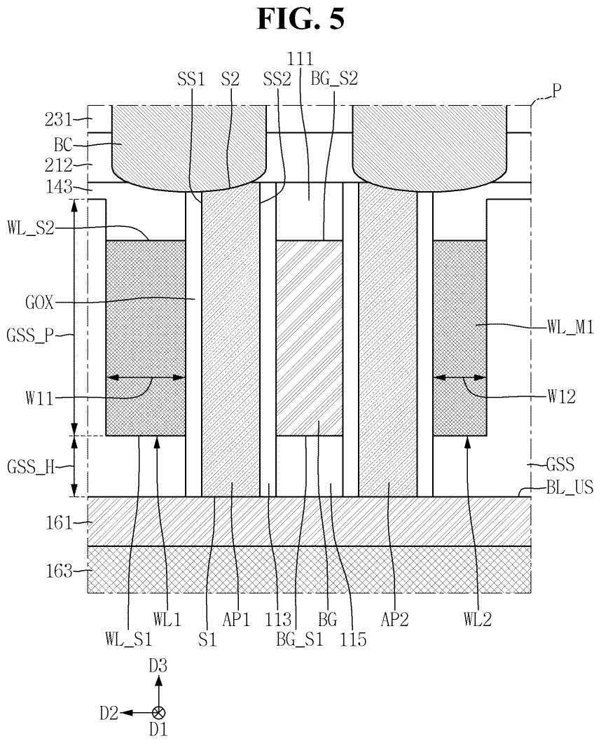

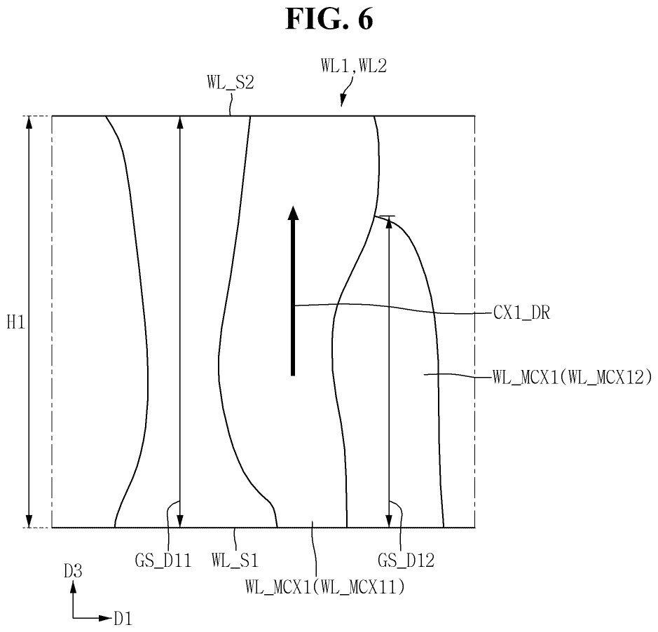

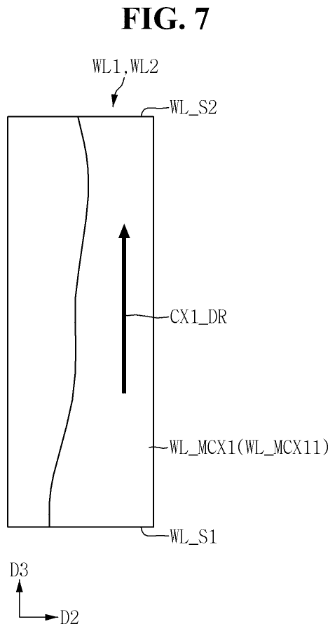

FIG. 1 is a layout diagram for explaining a semiconductor memory device according to some embodiments. FIG. 2 is a cross-sectional view taken along lines A-A and B-B of FIG. 1. FIG. 3 is a cross-sectional view taken along lines C-C and D-D of FIG. 1. FIGS. 4 and 5 are enlarged views of a portion P of FIG. 2. FIG. 6 is a diagram schematically showing a shape of a crystal grain of a cross section taken by cutting a word line of FIG. 4 in a first direction. FIG. 7 is a diagram schematically showing a shape of the crystal grain of a cross section taken by cutting the word line of FIG. 4 in a second direction.

The semiconductor memory device according to the embodiments of the present disclosure may include memory cells including a vertical channel transistor (VCT).

Referring to FIGS. 1 to 7, the semiconductor memory device according to some embodiments may include bit lines BL, word lines WL1 and WL2, back gate electrodes BG, a shielding conductive pattern SL, active patterns AP1 and AP2, and data storage patterns DSP.

The substrate 100 may be a silicon substrate or may include other materials, for example, but is not limited to, silicon germanium, indium antimonide, lead telluride, indium arsenide, indium phosphide, gallium arsenide or gallium antimonide.

Although not shown, the substrate 100 may include a cell array region in which a data storage pattern is disposed, and a peripheral circuit region defined around the cell array region.

A bonding insulating film 263 may be disposed on the substrate 100. The bonding insulating film 263 may be used to bond wafers. As an example, the bonding insulating film 263 may include silicon carbonitride (SiCN). As another example, the bonding insulating film 263 may include silicon oxide (SiO₂).

Shielding structures 171, SL and 175 may be disposed on the substrate 100. For example, the shielding structure 171, SL and 175 may be disposed on the bonding insulating film 263.

The shielding structures 171, SL, and 175 may include a shielding conductive pattern SL and shielding insulating films 171 and 175. For example, the shielding insulating films 171 and 175 may include a shielding insulating liner 171 and a shielding insulating capping film 175.

The shielding conductive pattern SL may include a plurality of shielding conductive line patterns SLp. Each shielding conductive line pattern SLp may extend in the second direction D2. Each shielding conductive line pattern SLp may be adjacent to each other in the first direction D1. For example, the first direction D1 and the second direction D2 may be horizontal directions that are horizontal or parallel to the substrate 100.

Each shielding conductive line pattern SLp may extend from the cell array region to the peripheral circuit region. An end part of the shielding conductive pattern SL may be disposed on the peripheral circuit region.

The shielding conductive pattern SL includes a conductive material. The shielding conductive pattern SL may include, for example, at least one of a conductive metal nitride, a conductive metal silicon nitride, a metal carbonitride, a conductive metal silicide, a conductive metal oxide, a two-dimensional material, and a metal.

A shielding insulating capping film 175 may be disposed on the substrate 100. The shielding insulating capping film 175 may be disposed between the substrate 100 and the shielding conductive pattern SL.

The shielding insulating capping film 175 may be in contact with the shielding conductive pattern SL. In the semiconductor memory device according to some embodiments, the shielding insulating capping film 175 may be in contact with the shielding conductive line pattern SLp.

The shielding insulating capping film 175 may have a linear shape extending in a second direction D2 along the shielding conductive line pattern SLp. Unlike the shown example, the shielding insulating capping film 175 may have a flat plate shape. In other words, the shielding insulating capping film 175 may overlap the shielding conductive line pattern SLp and the bit line BL in a third direction D3. For example, the third direction D3 may be a vertical direction that is perpendicular to the substrate 100.

The shielding insulating liner 171 may be disposed on the shielding conductive pattern SL. The shielding insulating liner 171 may extend along the profile of the shielding conductive line pattern SLp.

The shielding insulating liner 171 may be disposed on the bit line BL and the substrate 100. Unlike the shown example, the shielding insulating liner 171 may not be disposed between the bit line BL and a third peri-upper insulating film 265.

The shielding insulating liner 171 and the shielding insulating capping film 175 may each be made of an insulating material. When the shielding insulating liner 171 and the shielding insulating capping film 175 include the same material, a boundary between the shielding insulating liner 171 and the shielding insulating capping film 175 may not be distinguished.

Because the shielding structures 171, SL, and 175 are disposed between bit lines BL adjacent in the first direction D1, a coupling noise between the bit lines BL may be reduced.

The bit lines BL may be disposed on the substrate 100. For example, the bit lines BL may be disposed on the bonding insulating film 263.

The bit line BL may extend long in the second direction D2. The adjacent bit lines BL may be spaced apart in the first direction D1. The bit line BL includes a long side wall extending in the second direction D2, and a short side wall extending in the first direction D1.

The bit line BL may be disposed to be adjacent to the shielding conductive line pattern SLp. The bit line BL may be disposed to be adjacent to the shielding conductive line pattern SLp in the first direction D1. In other words, the shielding conductive line pattern SLp may extend in the second direction D2 along the long side wall of the bit line BL.

The bit line BL may be disposed between the shielding conductive line patterns SLp adjacent in the first direction D1. The bit line BL may be disposed on the shielding insulating liner 171. For example, the shielding insulating liner 171 may be in contact with the bit line BL.

Although not shown, each bit line BL may extend from the cell array region to the peripheral circuit region. The end part of each bit line BL may be disposed on the peripheral circuit region.

The bit line BL may include an upper surface BL_US and a bottom surface BL_BS that are opposite to each other in the third direction D3. The upper surface BL_US of the bit line may face a first active pattern AP1 and a second active pattern AP2, which will be described below. In the semiconductor memory device according to some embodiments, the shielding conductive pattern SL may not be disposed on the bottom surface BL_BS of the bit line.

Each bit line BL may include a semiconductor pattern 161, a metal pattern 163, and a bit line mask pattern 165 that are stacked in order. Unlike the shown example, as an example, the bit line BL may include one of the semiconductor pattern 161 and the metal pattern 163. As another example, the bit line BL may not include the bit line mask pattern 165.

The bit line BL may include a conductive bit line. The conductive bit line includes a film made of a conductive material among the bit lines BL. The conductive bit line may include the semiconductor pattern 161 and the metal pattern 163.

The semiconductor pattern 161 may include a conductive semiconductor material. The conductive semiconductor material may be, for example, a semiconductor material doped with impurities. The semiconductor pattern 161 may include at least one of polysilicon, polysilicon germanium, poly germanium, amorphous silicon, amorphous silicon germanium, and amorphous germanium.

The metal pattern 163 may include a conductive material including a metal. The metal pattern 163 may include, for example, at least one of conductive metal nitride, conductive metal silicon nitride, metal carbonitride, conductive metal silicide, conductive metal oxide, two-dimensional (2D) material, and metal. In the semiconductor memory device according to some embodiments, the two-dimensional material may be a metallic material and/or a semiconductor material. The 2D material may include a 2D allotrope or a 2D compound, and may include, but is not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed as an example, the 2D materials that may be included in the semiconductor memory device of the present disclosure are not limited by the above-mentioned materials.

The bit line mask pattern 165 may include an insulating material. The bit line mask pattern 165 may include, but is not limited to, silicon nitride or silicon oxynitride.

The first active patterns AP1 and the second active patterns AP2 may be disposed on each bit line BL. The first active patterns AP1 and the second active patterns AP2 may be alternately disposed along the second direction D2.

The first active patterns AP1 may be spaced apart from each other in the first direction D1. The first active patterns AP1 may be spaced apart at regular intervals. The second active patterns AP2 may be spaced apart from each other in the first direction D1. The second active patterns AP2 may be spaced apart at regular intervals. The first active pattern AP1 may be spaced apart from the second active pattern AP2 in the second direction D2. The first active patterns AP1 and the second active patterns AP2 may be arranged two-dimensionally along the first direction D1 and the second direction D2 that intersect each other.

For example, each of the first active pattern AP1 and the second active pattern AP2 may be formed of a single crystal semiconductor material. As an example, each of the first active pattern AP1 and the second active pattern AP2 may be formed of single crystal silicon.

The first active pattern AP1 and the second active pattern AP2 may each have a length in the first direction D1, a width in the second direction D2, and a height in the third direction D3. Each of the first active pattern AP1 and the second active pattern AP2 may have a substantially uniform width. That is, each of the first active pattern AP1 and the second active pattern AP2 may have substantially the same width on the first and second surfaces S1 and S2. Further, the width of the first active pattern AP1 may be identical to the width of the second active pattern AP2.

The width of the first active pattern AP1 and the width of the second active pattern AP2 may range from several nm to several tens of nm. For example, the width of the first active pattern AP1 and the width of the second active pattern AP2 may be, but is not limited to, 1 nm to 30 nm, such as 1 nm to 10 nm. Lengths of each of the first and second active patterns AP1 and AP2 may be greater than a line width of the bit line BL. That is, the lengths of each of the first and second active patterns AP1 and AP2 may be greater than the width of the bit line BL in the first direction D1.

In FIG. 4, each of the first active pattern AP1 and the second active pattern AP2 includes a first surface S1 and a second surface S2 that are opposite to each other in the third direction D3. For example, the first surfaces S1 of the first and second active patterns AP1 and AP2 may face the bit line BL. The second surfaces S2 of the first and second active patterns AP1 and AP2 may look at the contact pattern BC.

The first surfaces S1 of the first and second active patterns AP1 and AP2 are connected to the bit line BL. For example, the first surfaces S1 of the first and second active patterns AP1 and AP2 may be connected to the semiconductor pattern 161 of the bit line BL. Unlike the shown example, when the semiconductor pattern 161 is omitted, the first surfaces S1 of the first and second active patterns AP1 and AP2 may be connected to the metal pattern 163. The second surfaces S2 of the first and second active patterns AP1 and AP2 may be connected to the contact patterns BC.

Each of the first active pattern AP1 and the second active pattern AP2 may include a first side wall SS1 and a second side wall SS2 that are opposite to each other in the second direction D2. The second side wall SS2 of the first active pattern AP1 may face the first side wall SS1 of the second active pattern AP2.

The first side wall SS1 of the first active pattern AP1 may be adjacent to the first word line WL1. The second side wall SS2 of the second active pattern AP2 may be adjacent to the second word line WL2.

Although not shown, as an example, each of the first active pattern AP1 and the second active pattern AP2 may include a first dopant region adjacent to the bit line BL, and a second dopant region adjacent to the contact pattern BC. Each of the first active pattern AP1 and the second active pattern AP2 may include a channel region between the first dopant region and the second dopant region. The first dopant region and the second dopant region are regions doped with a dopant in the first active pattern AP1 and the second active pattern AP2. Unlike the aforementioned example, each of the first active pattern AP1 and the second active pattern AP2 may not include at least one of the first dopant region and the second dopant region.

At the time of operation of the semiconductor memory device, the channel region of the first and second active patterns AP1 and AP2 may be controlled by the first and second word lines WL1 and WL2 and the back gate electrodes BG. Since the first and second active patterns AP1 and AP2 are made of a single crystal semiconductor material, leakage current characteristics of the semiconductor memory device may be improved.

The back gate electrodes BG may be disposed on the bit line BL and the shielding conductive pattern SL. The back gate electrodes BG may be spaced apart from each other in the second direction D2. The back gate electrodes BG may be spaced apart at regular intervals. Each back gate electrode BG may extend in the first direction D1 across the bit line BL.

Each back gate electrode BG may be disposed between a first active pattern AP1 and a second active pattern AP2 that are adjacent to each other in the second direction D2. That is to say, the first active pattern AP1 may be disposed on one side of each back gate electrode BG, and the second active pattern AP2 may be disposed on the other side of each back gate electrode BG. The height of the back gate electrode BG in the third direction D3 may be smaller than the heights of the first and second active patterns AP1 and AP2.

Each back gate electrode BG may be disposed between the second side wall SS2 of the first active pattern AP1 and the first side wall SS1 of the second active pattern AP2. Each back gate electrode BG may be disposed on the second side wall SS2 of the first active pattern AP1 and the first side wall SS1 of the second active pattern AP2.

The first active pattern AP1 may be disposed between the first word line WL1 and the back gate electrode BG. The second active pattern AP2 may be disposed between the second word line WL2 and the back gate electrode BG. A pair of first word line WL1 and second word line WL2 may be disposed between the back gate electrodes BG adjacent to each other in the second direction D2.

The back gate electrode BG may include a first surface BG_S1 and a second surface BG_S2 that are opposite to each other in the third direction D3. The first surface BG_S1 of the back gate electrode is closer to the bit line BL than the second surface BG_S2 of the back gate electrode.

The back gate electrode BG may include a first surface BG_S1 and a second surface BG_S2 that are opposite to each other in the third direction D3. The first surface BG_S1 of the back gate electrode is closer to the bit line BL than the second surface BG_S2 of the back gate electrode. The first surface BG_S1 of the back gate electrode may face the bit line BL.

The back gate electrode BG includes a conductive material, and may include, for example, at least one of a conductive semiconductor material, conductive metal nitride, conductive metal silicon nitride, metal carbonitride, conductive metal silicide, conductive metal oxide, a two-dimension material, and a metal.

A voltage is applied to the back gate electrode BG at the time of operation of the semiconductor memory device, and the threshold voltage of the vertical channel transistor may be adjusted. Since the threshold voltage of the vertical channel transistor is adjusted, leakage current characteristics may be prevented from deteriorating.

A back gate capping pattern 111 may be disposed between the first active pattern AP1 and the second active pattern AP2 adjacent to each other in the second direction D2. The back gate capping pattern 111 may extend in the first direction D1 along with the back gate electrode BG. The back gate capping pattern 111 may be disposed on the second surface BG_S2 of the back gate electrode.

The back gate capping pattern 111 may be made of an insulating material. The back gate capping pattern 111 may include, for example, but is not limited to, a silicon oxide film, a silicon oxynitride film or a silicon nitride film.

A back gate insulating pattern 113 may be disposed between the back gate electrode BG and the first active pattern AP1, and between the back gate electrode BG and the second active pattern AP2. The back gate insulating pattern 113 may be disposed between the back gate capping pattern 111 and the first active pattern AP1, and between the back gate capping pattern 111 and the second active pattern AP2.

The back gate insulating pattern 113 may be made of an insulation material. The back gate insulating pattern 113 may include, for example, a silicon oxide film, a silicon oxynitride film, a high dielectric constant insulating film having a higher dielectric constant than a silicon oxide film, or a combination thereof.

The back gate capping pattern 115 may be disposed between the bit line BL and the back gate electrode BG. The back gate capping pattern 115 may be disposed between the first active pattern AP1 and the second active pattern AP2 adjacent to each other in the second direction D2. In the back gate capping pattern 115, the bit line BL may extend in the first direction D1 along with the back gate electrode BG. In the back gate capping pattern 115, the bit line BL may be disposed on the first surface BG_S1 of the back gate electrode. The thickness of the back gate capping pattern 115 between the bit lines BL may be different from the thickness of the back gate capping pattern 115 on the bit line BL, but the present disclosure is not limited thereto.

The back gate capping pattern 115 may be made of an insulating material. The back gate capping pattern 115 may include, for example, but is not limited to, at least one of a silicon oxide film, a silicon oxynitride film, and a silicon nitride film.

The first word line WL1 and the second word line WL2 may be disposed on the bit line BL and the shielding conductive pattern SL. Each of the first word line WL1 and the second word line WL2 may extend in the first direction D1. The first word lines WL1 and the second word lines WL2 may be alternately arranged in the second direction D2.

The first word line WL1 may be disposed on the first side wall SS1 of the first active pattern AP1. The second word line WL2 may be disposed on the second side wall SS2 of the second active pattern AP2. The first active patterns AP1 and the second active patterns AP2 may be disposed between the first word line WL1 and the second word line WL2 adjacent to each other in the second direction D2.

The first word line WL1 and the second word line WL2 may be spaced apart from the bit line BL and the contact pattern BC in the third direction D3. The first word line WL1 and the second word line WL2 may be located between the bit line BL and the contact pattern BC.

Each of the first word line WL1 and the second word line WL2 may have a width in the second direction D2. The width of the first word line WL1 and the width of the second word line WL2 on the bit line BL may be different from the width of the first word line WL1 and the width of the second word line WL2 on the shielding conductive pattern SL.

For example, each of the first word line WL1 and the second word line WL2 may include a first portion WLa of the word line and a second portion WLb of the word line. A width of the first portion WLa of the word line in the second direction D2 may be smaller than a width of the second portion WLb of the word line in the second direction D2. As an example, the first portion WLa of the word line may be disposed on the bit line BL. The second portion WLb of the word line may be disposed on the shielding conductive pattern SL.

Each of the first word line WL1 and the second word line WL2 may include the first portion WLa of the word line and the second portion WLb of the word line that are alternately disposed along the first direction D1. In the first word line WL1, each first active pattern AP1 may be disposed between the second portions WLb of the word lines adjacent in the first direction D1. In the second word line WL2, each second active pattern AP2 may be disposed between the second portions WLb of word lines adjacent in the first direction D1.

Unlike the shown example, the width of the first portion WLa of the word line in the second direction D2 may be identical to the width of the second portion WLb of the word line in the second direction D2.

In FIG. 4, a width W11 of the first word line WL1 in the second direction D2 may be identical to a width W12 of the second word line WL2 in the second direction D2.

In FIG. 5, the width W11 of the first word line WL1 in the second direction D2 may be different from the width W12 of the second word line WL2 in the second direction D2. As another example, the width W11 of the first word line WL1 in the second direction D2 may be larger than the width W12 of the second word line WL2 in the second direction D2.

The first word line WL1 and the second word line WL2 may include a first surface WL_S1 and a second surface WL_S2 that are opposite to each other in the third direction D3. The first surface WL_S1 of the first and second word lines is closer to the bit line BL than the second surface WL_S2 of the first and second word lines. The first surface WL_S1 of the first and second word lines look at the bit line BL.

The first word line WL1 will be explained as an example. As an example, the height of the first word line WL1 in the third direction D3 may be identical to the height of the back gate electrode BG in the third direction D3. As another example, the height of the first word line WL1 in the third direction D3 may be greater than the height of the back gate electrode BG in the third direction D3. As yet another example, the height of the first word line WL1 in the third direction D3 may be smaller than the height of the back gate electrode BG in the third direction D3.

Further, as an example, the height of the first surface WL_S1 of the first word line may be identical to the height of the first surface BG_S1 of the back gate electrode on the basis of the upper face BL_US of the bit line. As another example, the first surface WL_S1 of the first word line may be higher than the first surface BG_S1 of the back gate electrode. As yet another example, the first surface WL_S1 of the first word line may be lower than the first surface BG_S1 of the back gate electrode.

In addition, as an example, the height of the second surface WL_S2 of the first word line may be identical to the height of the second surface BG_S2 of the back gate electrode on the basis of the upper face BL_US of the bit line. As another example, the second surface WL_S2 of the first word line may be higher than the second surface BG_S2 of the back gate electrode. As yet another example, the second surface WL_S2 of the first word line may be lower than the second surface BG_S2 of the back gate electrode.

The first surfaces WL_S1 of the first and second word lines WL1 and WL2 may form a plane. Unlike the shown example, as an example, the first surfaces WL_S1 of the first and second word lines WL1 and WL2 may be concavely rounded. As another example, each of the first word line WL1 and the second word line WL2 may have the form of a spacer. In other words, the first surfaces WL_S1 of the first and second word lines WL1 and WL2 may be convexly rounded.

The second surface WL_S2 of the first and second word lines WL1 and WL2 may be a plane. Unlike the shown example, the second surface WL_S2 of the first and second word lines WL1 and WL2 may have a concavely curved face. Although the first surface BG_S1 of the back gate electrode and the second surface BG_S2 of the back gate electrode are shown as forming a plane, the embodiment is not limited thereto.

In FIGS. 4, 6, and 7, the first word line WL1 and the second word line WL2 may include a first word line pattern WL_M1 including a first conductive material. The first word line WL1 and the second word line WL2 may include a plurality of first conductive material crystals WL_MCX1. Each first conductive material crystal WL_MCX1 may be a crystal grain of the first conductive material.

A crystal direction CX1_DR of each first conductive material crystal WL_MCX1 may be a third direction D3. In other words, the crystal direction CX1_DR of the first conductive material crystal WL_MCX1 may be a vertical direction that is perpendicular to the substrate 100. As used herein, the “crystal direction” may refer to a direction in which a crystal lattice, which comprises a plurality of atoms, of the given conductive material crystal extend. Each first conductive material crystal WL_MCX1 may be oriented in the third direction D3. The first word line pattern WL_M1 includes a plurality of first conductive material crystals WL_MCX1 whose crystal direction CX1_DR is the vertical direction.

For example, the first conductive material crystal WL_MCX1 included in the first word line pattern WL_M1 may be formed through a bottom-up growth method.

The first word line WL1 will be explained as an example. The description of the first word line WL1 may be applied to the second word line WL2.

At least one of the first surface WL_S1 of the first word line WL1 and the second surface WL_S2 of the first word line WL1 may be defined by the first word line pattern WL_M1. In other words, at least one of the first surface WL_S1 of the first word line WL1 and the second surface WL_S2 of the first word line WL1 may be defined by a plurality of first conductive material crystals WL_MCX1. That is, at least one of the first surface WL_S1 of the first word line WL1 and the second surface WL_S2 of the first word line WL1 may be formed by collection of the plurality of first conductive material crystals WL_MCX1.

In the semiconductor memory devices according to some embodiments, the first surface WL_S1 of the first word line WL1 and the second surface WL_S2 of the first word line WL1 may be defined by the first word line pattern WL_M1. The first surface WL_S1 of the first word line WL1 and the second surface WL_S2 of the first word line WL1 may be defined by a plurality of first conductive material crystals WL_MCX1.

At least one of the plurality of first conductive material crystals WL_MCX1 may extend from the first surface WL_S1 of the first word line WL1 to the second surface WL_S2 of the first word line WL1. In other words, the height of at least one of the plurality of first conductive material crystals WL_MCX1 may be identical to the height H1 of the first word line WL1 in the third direction D3.

The plurality of first conductive material crystals WL_MCX1 may include a first sub-conductive material crystal WL_MCX11 and a second sub-conductive material crystal WL_MCX12. Each of the first sub-conductive material crystal WL_MCX11 and the second sub-conductive material crystal WL_MCX12 may be a crystal grain of the first conductive material included in the first word line pattern WL_M1. The crystal direction CX1_DR of the first sub-conductive material crystal WL_MCX11 and the crystal direction CX1_DR of the second sub-conductive material crystal WL_MCX12 may each be the third direction D3 (that is, the vertical direction).

The first sub-conductive material crystal WL_MCX11 may extend from the first surface WL_S1 of the first word line WL1 to the second surface WL_S2 of the first word line WL1. A height GS_D11 of the first sub-conductive material crystal WL_MCX11 in the third direction D3 may be identical to a height H1 of the first word line WL1 in the third direction D3.

A height GS_D12 of the second sub-conductive material crystal WL_MCX12 in the third direction D3 is smaller than the height GS_D11 of the first sub-conductive material crystal WL_MCX11 in the third direction D3. The height GS_D12 of the second sub-conductive material crystal WL_MCX12 in the third direction D3 is smaller than the height H1 of the first word line WL1 in the third direction D3.

For example, the second sub-conductive material crystal WL_MCX12 may define a part of the first surface WL_S1 of the first word line WL1. The second sub-conductive material crystal WL_MCX12 does not extend to the second surface WL_S2 of the first word line WL1. Unlike the shown example, the second sub-conductive material crystal WL_MCX12 may define a part of the second surface WL_S2 of the first word line WL1.

The height GS_D11 of the first sub-conductive material crystal WL_MCX11 may be a crystal grain size of the first sub-conductive material crystal WL_MCX11 in the third direction D3. The height GS_D12 of the second sub-conductive material crystal WL_MCX12 may be a crystal grain size of the second sub-conductive material crystal WL_MCX12 in the third direction D3.

The first word line WL1 and the second word line WL2 may include a conductive material. The first word line WL1 and the second word line WL2 may include, for example, at least one of a conductive metal nitride, a conductive metal silicon nitride, a metal carbonitride, a conductive metal oxide, and a metal. For example, the first word line pattern WL_M1 may include a conductive material that may be selectively grown. The first word line pattern WL_M1 may include, for example, but is not limited to, one of titanium nitride (TiN), titanium (Ti), tungsten (W), molybdenum (Mo), ruthenium (Ru), and cobalt (Co).

Since the first word line WL1 and the second word line WL2 include a plurality of first conductive material crystals WL_MCX1 having a crystal direction in the vertical direction D3, the crystal grain size of the first conductive material crystal WL_MCX1 included in the first word line WL1 and the second word line WL2 increases. As the grain size of the first conductive material crystal WL_MCX1 increases, the number of grain boundaries in the first word line WL1 and the second word line WL2 may decrease. Electrons flowing through the first word line WL1 and the second word line WL2 may be scattered at the grain boundary between the first conductive material crystals WL_MCX1. When the number of scattering of electrons flowing through the first word line WL1 and the second word line WL2 increases, the resistance of the first word line WL1 and the second word line WL2 may increase.

However, since the first word line WL1 and the second word line WL2 include the plurality of first conductive material crystals WL_MCX1 having a crystal direction in the vertical direction D3, the number of scattering of the electrons flowing through the first word line WL1 and the second word line WL2 may decrease. That is, the resistance of the first word line WL1 and the second word line WL2 may decrease. Accordingly, the performance and reliability of the semiconductor memory device according to some embodiments of the present disclosure may be improved.

Gate insulating patterns GOX may be disposed between the first word line WL1 and the first active pattern AP1, and between the second word line WL2 and the second active pattern AP2. The gate insulating pattern GOX may extend in the first direction D1 along with the first word line WL1 and the second word line WL2.

The gate insulating pattern GOX may include a silicon oxide film, a silicon oxynitride film, a high dielectric constant insulating film having a higher dielectric constant than a silicon oxide film, or a combination thereof. The high dielectric constant insulating film may include, for example, but is not limited to, at least one of metal oxide, metal oxynitride, metal silicon oxide, and metal silicon oxynitride.

The gate insulating pattern GOX may extend along the first side wall SS1 of the first active pattern AP1, and may extend along the second side wall SS2 of the second active pattern AP2. In the semiconductor memory device according to some embodiments, in a cross-sectional view, the gate insulating pattern GOX between the first active pattern AP1 and the first word line WL1 may be separated from the gate insulating pattern GOX between the second active pattern AP2 and the second word line WL2.

The gate capping pattern 143 may be disposed between the first word line WL1 and the contact pattern BC, and between the second word line WL2 and the contact pattern BC. The gate capping pattern 143 may cover the second surface WL_S2 of the first and second word lines WL1 and WL2.

The gate separation pattern GSS may be disposed on the bit line BL. The gate separation pattern GSS may be disposed between the bit line BL and the contact pattern BC. The gate separation pattern GSS may be in contact with the upper face BL_US of the bit line.

The gate separation pattern GSS may be disposed between the first word line WL1 and the second word line WL2 adjacent to each other in the second direction D2. The first word line WL1 and the second word line WL2 may be separated by the gate separation pattern GSS. The gate separation pattern GSS may extend in the first direction D1 between the first word line WL1 and the second word line WL2.

The first word line WL1 may be disposed between the gate separation pattern GSS and the first active pattern AP1. The second word line WL2 may be disposed between the gate separation pattern GSS and the second active pattern AP2.

The gate separation pattern GSS may include a horizontal portion GSS_H and a protruding portion GSS_P. The protruding portion GSS_P of the gate separation pattern may protrude from the horizontal portion GSS_H of the gate separation pattern in the third direction D3.

The horizontal portion GSS_H of the gate separation pattern may be closer to the bit line BL than the protruding portion GSS_P of the gate separation pattern. The horizontal portion GSS_H of the gate separation pattern may be in contact with the bit line BL. The width of the horizontal portion GSS_H of the gate separation pattern in the second direction D2 is greater than the width of the protruding portion GSS_P of the gate separation pattern in the second direction D2.

The protruding portion GSS_P of the gate separation pattern may be disposed between the side wall of the first word line WL1 and the side wall of the second word line WL2 that face each other. The horizontal portion GSS_H of the gate separation pattern may cover the first surface WL_S1 of the first and second word lines WL1 and WL2.

The first word line WL1 and the second word line WL2 are disposed on the horizontal portion GSS_H of the gate separation pattern. The first word line WL1 and the second word line WL2 may be on the horizontal portion GSS_H of the gate separation pattern. The first word line WL1 and the second word line WL2 may be disposed between the horizontal portion GSS_H of the gate separation pattern and the contact pattern BC.

The gate separation pattern GSS may be made of an insulating material. Unlike the shown example, the gate separation pattern GSS may include a plurality of insulating films.

The contact patterns BC may penetrate or extend into the contact interlayer insulating film 231 and the contact etching stop film 212. The contact patterns BC may be connected to each of the first active pattern AP1 and the second active pattern AP2. The contact patterns BC may be connected to each of the second surface S2 of the first and second active patterns AP1 and AP2. In a plan view, each contact pattern BC may have various shapes such as a circle, an ellipse, a rectangle, a square, a rhombus, and a hexagon.

The contact pattern BC may include a conductive material. The contact pattern BC may include, for example, at least one of doped polysilicon, conductive metal nitride, conductive metal silicon nitride, metal carbonitride, conductive metal silicide, conductive metal oxide, two-dimensional material, and metal.

A contact etching stop film 212 may be disposed on the gate capping pattern 143 and the back gate capping pattern 111. Each of the contact interlayer insulating film 231 and the contact etching stop film 212 may be made of an insulating material.

Landing pads LP may be disposed on the contact pattern BC. In a plan view, the landings pad LP may have various shapes, such as a circle, an ellipse, a rectangle, a square, a rhombus, and a hexagon.

Pad separation insulating patterns 235 may be disposed between the landing pads LP. In a plan view, the landing pads LP may be arranged in the form of a matrix along the first direction D1 and the second direction D2. The upper surface of the landing pad LP may be substantially coplanar with the upper surface of the pad separation insulating pattern 235, but the present disclosure is not limited thereto.

The landing pad LP includes a conductive materials, and may include, for example, at least one of doped polysilicon, conductive metal nitride, conductive metal silicon nitride, metal carbonitride, conductive metal silicide, conductive metal oxide, a 2D material and a metal.

Each of the data storage patterns DSP may be disposed on the landing pads LP. The data storage patterns DSP may be electrically connected to each of the first and second active patterns AP1 and AP2. The data storage patterns DSP may be arranged in the form of a matrix along the first direction D1 and the second direction D2, as shown in FIG. 1. The data storage patterns DSP may completely or partially overlap the landing pads LP in the third direction D3. The data storage patterns DSP may be in contact with all or part of the upper surface of the landing pad LP.

As an example, the data storage patterns DSP may be a capacitor. The data storage patterns DSP may include a capacitor dielectric film 253 interposed between storage electrodes 251 and a plate electrode 255. For example, the storage electrode 251 may be in contact with the landing pad LP. In a plan view, the storage electrode 251 may have various shapes such as a circle, an ellipse, a rectangle, a square, a rhombus, and a hexagon. The data storage patterns DSP may be in contact with all or part of the upper surface of the landing pad LP. The storage electrodes 251 may pass or extend through the upper etching stop film 247. The upper etching stop film 247 may be made of an insulating material.

The storage electrode 251 and the plate electrode 255 may each include, for example, at least one of a conductive semiconductor material, conductive metal nitride, conductive metal silicon nitride, metal carbonitride, conductive metal silicide, conductive metal oxide, and a metal. The capacitor dielectric film 253 may include at least one of a ferroelectric material, an antiferroelectric material, and a paraelectric material. For example, the capacitor dielectric film 253 may include one of the ferroelectric material, the antiferroelectric material, the paraelectric material, combinations of the ferroelectric material and antiferroelectric material, combinations of the ferroelectric material and paraelectric material, combinations of paraelectric material and antiferroelectric material, and combinations of the ferroelectric material, the antiferroelectric material and the paraelectric material.

In contrast, the data storage patterns DSP may be variable resistance patterns that may be switched between two resistance states by electrical pulses applied to the memory element. For example, the data storage patterns DSP may include a phase-change material, perovskite compounds, transition metal oxide, magnetic materials, ferromagnetic materials or antiferromagnetic materials.

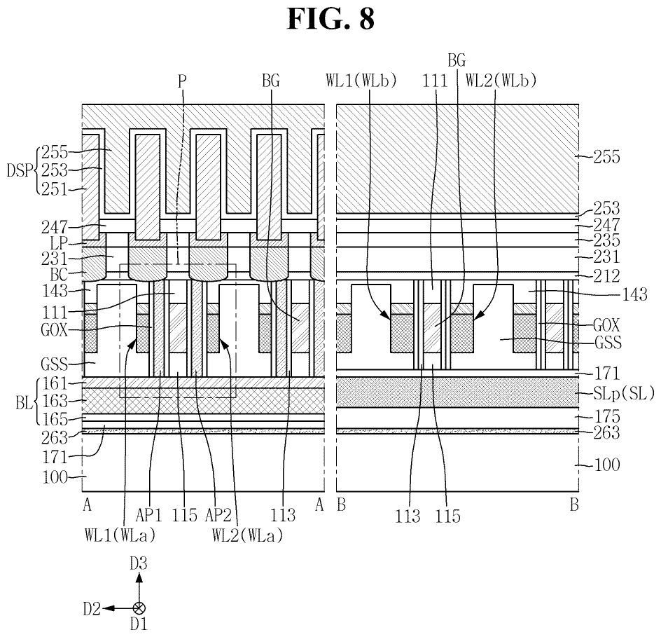

FIGS. 8 to 11 are diagrams for explaining a semiconductor memory device according to some embodiments. For convenience of explanation, points different from those described using FIGS. 1 to 7 will be mainly explained.

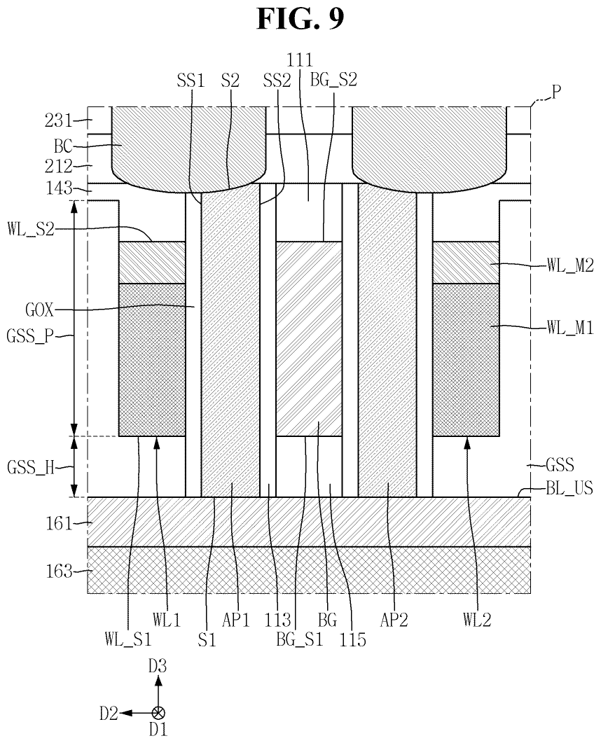

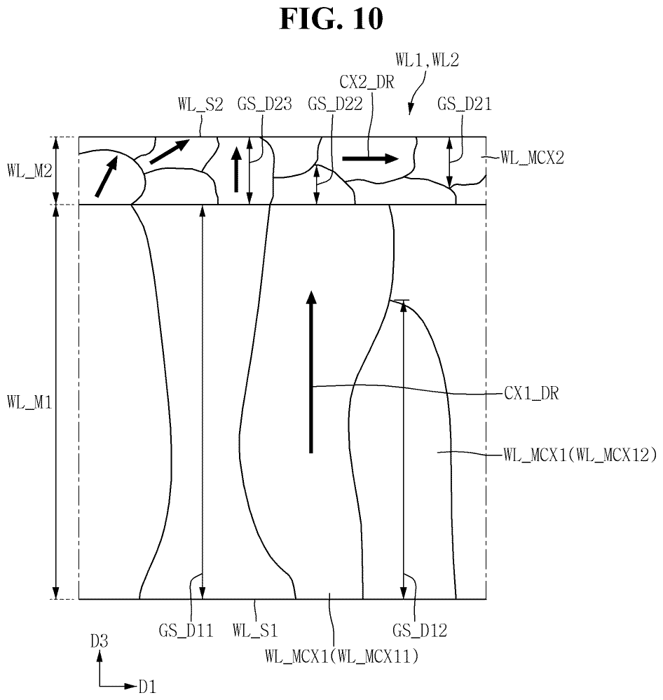

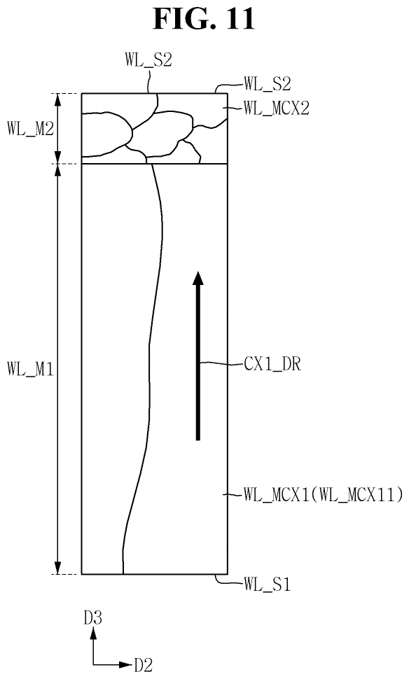

For reference, FIG. 8 is a cross-sectional view taken along lines A-A and B-B of FIG. 1. FIG. 9 is an enlarged view of a portion P of FIG. 8. FIG. 10 is a diagram schematically showing the crystal grain shape of a cross section taken by cutting the word line of FIG. 9 in the first direction. FIG. 11 is a diagram schematically showing the crystal grain shape of a cross section taken by cutting the word line of FIG. 9 in the second direction.

Referring to FIGS. 8 and 9, in the semiconductor memory device according to some embodiments, the first word line WL1 and the second word line WL2 may include a first word line pattern WL_M1 including a first conductive material, and a second word line pattern WL_M2 including a second conductive material.

The first word line WL1 and the second word line WL2 may include a plurality of first conductive material crystals WL_MCX1 and a plurality of second conductive material crystals WL_MCX2. The second word line pattern WL_M2 may include a plurality of second conductive material crystals WL_MCX2. Each second conductive material crystal WL_MCX2 may be a crystal grain of the second conductive material.

Each second conductive material crystal WL_MCX2 may have a random crystal direction CX2_DR. In other words, each second conductive material crystal WL_MCX2 may be oriented in a random direction.

The first word line WL1 will be explained as an example. The explanation of the first word line WL1 may be applied to the second word line WL2.

A first surface WL_S1 of the first word line WL1 may be defined by the first word line pattern WL_M1. A second surface WL_S2 of the first word line WL1 may be defined by the second word line pattern WL_M2. The second surface WL_S2 of the first word line WL1 may be defined by a plurality of second conductive material crystals WL_MCX2. The second surface WL_S2 of the first word line WL1 may be formed by collection of the plurality of second conductive material crystals WL_MCX2.

Unlike the shown example, the second surface WL_S2 of the first word line WL1 may be defined by the first word line pattern WL_M1. The first surface WL_S1 of the first word line WL1 may be defined by the second word line pattern WL_M2.

The second conductive material crystal WL_MCX2 may have a random crystal direction CX2_DR, and the crystal grain size of each second conductive material crystal WL_MCX2 may be small. The grain sizes GS_D21, GS_D22, and GS_D23 of each second conductive material crystal WL_MCX2 in the third direction D3 is smaller than the grain sizes GS_D11 and GS_D12 of each first conductive material crystal WL_MCX1 in the third direction D3.

For example, the first conductive material crystal WL_MCX1 included in the first word line pattern WL_M1 may have a first average crystal grain size in the third direction D3. The first average crystal grain size may be an average value of the crystal grain sizes GS_D11 and GS_D12 of the first conductive material crystal WL_MCX1 in the third direction D3.

The second conductive material crystal WL_MCX2 included in the second word line pattern WL_M2 may have a second average crystal grain size in the third direction D3. The second average crystal grain size may be an average value of the crystal grain sizes GS_D21, GS_D22, and GS_D23 of the second conductive material crystal WL_MCX2 in the third direction D3.

For example, the first average grain size may be equal to or greater than three times the second average grain size.

The second word line pattern WL_M2 may include, for example, at least one of a conductive semiconductor material, conductive metal nitride, conductive metal silicon nitride, metal carbonitride, conductive metal silicide, conductive metal oxide, and a metal.

As an example, the second conductive material included in the second word line pattern WL_M2 may be identical to the first conductive material included in the first word line pattern WL_M1. That is, the second conductive material crystal WL_MCX2 may include the same conductive material as the first conductive material crystal WL_MCX1. Although the first word line pattern WL_M1 includes material identical to that of the second word line pattern WL_M2, a boundary between the first word line pattern WL_M1 and the second word line pattern WL_M2 may be distinguished. Since the crystal direction CX1_DR of the first conductive material crystal WL_MCX1 is distinguished from the crystal direction CX2_DR of the second conductive material crystal WL_MCX2, the boundary between the first word line pattern WL_M1 and the second word line pattern WL_M2 may be distinguished.

As another example, the second conductive material included in the second word line pattern WL_M2 may be different from the first conductive material included in the first word line pattern WL_M1.

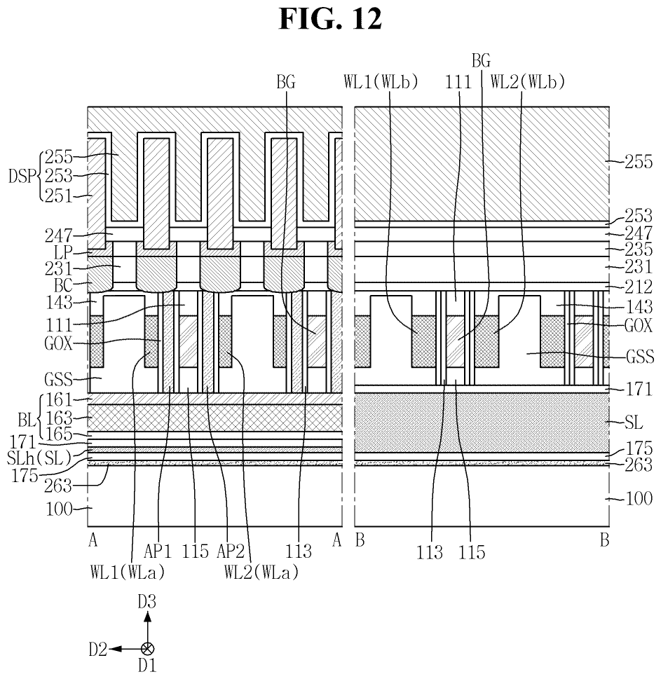

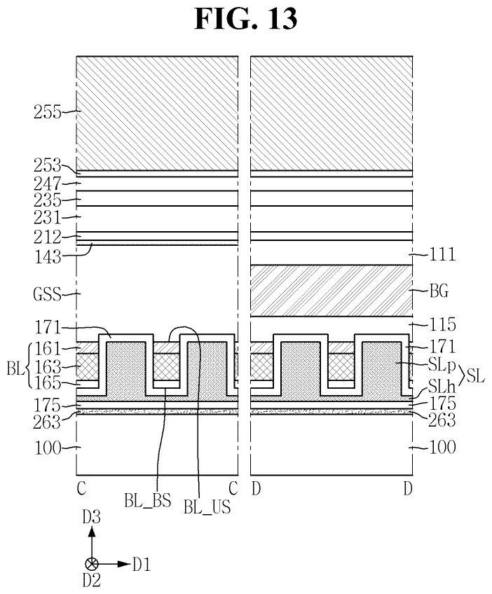

FIGS. 12 and 13 are diagrams for explaining a semiconductor memory device according to some embodiments. For convenience of explanation, points different from those described using FIGS. 1 to 7 will be mainly explained.

Referring to FIGS. 12 and 13, in the semiconductor memory device according to some embodiments, the shielding conductive pattern SL may include a shielding conductive plate SLh and a plurality of shielding conductive line patterns SLp.

The shielding conductive plate SLh may have a flat plate shape. The shielding conductive line pattern SLp may protrude or extend from the shielding conductive plate SLh in the third direction D3. The shielding conductive line pattern SLp is directly connected to the shielding conductive plate SLh.

The shielding insulating liner 171 may extend along the profiles of the shielding conductive plate SLh and the shielding conductive line pattern SLp.

The shielding insulating capping film 175 may be disposed between the shielding conductive plate SLh and the substrate 100. The shielding insulating capping film 175 may be in contact with the shielding conductive plate SLh.

The bit line BL may be disposed on the shielding conductive pattern SL. The bit line BL may be disposed on the shielding conductive plate SLh. The shielding conductive pattern SL may be disposed on the bottom surface BL_BS of the bit line. For example, the shielding conductive plate SLh may be disposed on the bottom surface BL_BS of the bit line.

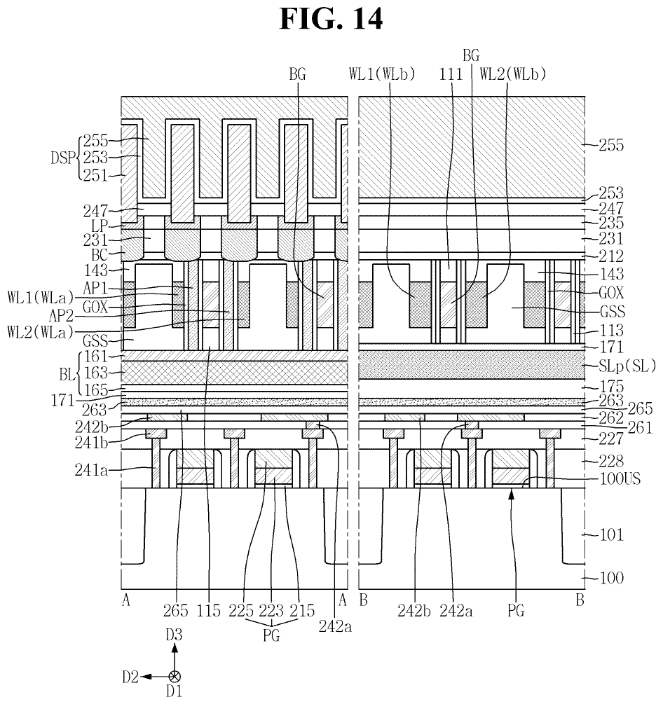

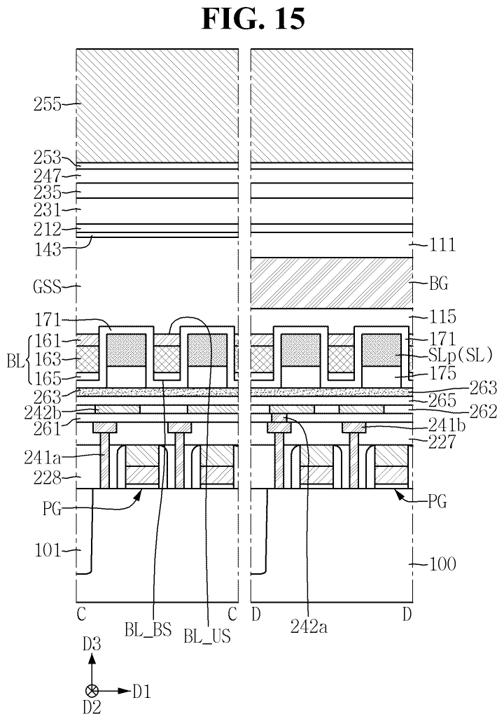

FIGS. 14 and 15 are diagrams for explaining a semiconductor memory device according to some embodiments. For convenience of explanation, points different from those described using FIGS. 1 to 13 will be mainly explained.

Referring to FIGS. 14 and 15, the semiconductor memory device according to some embodiments may further include a peri-gate structure PG disposed between the substrate 100 and the bit line BL.

The peri-gate structure PG may be disposed on the substrate 100. For example, the peri-gate structure PG may be disposed on the upper surface 100US of the substrate. The peri-gate structure PG may be disposed over the cell array region and the peripheral circuit region. In other words, a part of the peri-gate structure PG may be disposed in the cell array region of the substrate 100, and the remainder of the peri-gate structure PG may be disposed in the peripheral circuit region of the substrate 100.

The peri-gate structure PG may be included in a sensing transistor, a transfer transistor, a drive transistor, and the like. For example, the peri-gate structure PG included in the sensing transistor may be disposed on the cell array region of the substrate 100, but the present disclosure is not limited thereto. The types of transistors in the peripheral circuit disposed on the cell array region of the substrate 100 may vary depending on the design and layout of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a higher dielectric constant than a silicon oxide film, or a combination thereof. The high dielectric constant insulating film may include, for example, but is not limited to, at least one of metal oxide, metal oxynitride, metal silicon oxide, and metal silicon oxynitride.

The peri-lower conductive pattern 223 and the peri-upper conductive pattern 225 each include a conductive material. For example, the peri-lower conductive pattern 223 and the peri-upper conductive pattern 225 may each include at least one of a doped semiconductor material, conductive metal nitride, conductive metal silicon nitride, metal carbonitride, conductive metal silicide, conductive metal oxide, two-dimensional (2D) material, and metal. Although the peri-gate structure PG is shown to include a plurality of conductive patterns, the embodiment is not limited thereto.

Although it is not shown, the peri-gate structure PG may further include a peri-gate mask pattern disposed on the peri-upper conductive pattern 225. The peri-gate mask pattern is made up of an insulating material.

A first peri-lower insulating film 227 and a second peri-lower insulating film 228 are disposed on the upper surface 100US of the substrate. The first peri-lower insulating film 227 and the second peri-lower insulating film 228 each include an insulating material.

A peri-contact plug 241a and a peri-wiring line 241b may be disposed inside the first peri-lower insulating film 227 and the second peri-lower insulating film 228. The peri-contact plug 241a and the peri-wiring line 241b may be connected to the conductive patterns 223 and 225 of the peri-gate structure PG. Although not shown, the peri-contact plug 241a and the peri-wiring line 241b may be connected to a source/drain region disposed on at least one side of the peri-gate structure PG.

Although the peri-contact plug 241a and the peri-wiring line 241b are shown as being different films from each other, the present disclosure is not limited thereto. A boundary between the peri-contact plug 241a and the peri-wiring line 241b may not be distinguished. The peri-contact plug 241a and the peri-wiring line 241b each include a conductive material.

A first peri-upper insulating film 261 and a second peri-upper insulating film 262 may be disposed on the peri-contact plug 241a and the peri-wiring line 241b. The first peri-upper insulating film 261 and the second peri-upper insulating film 262 each include an insulating material. Unlike the shown example, an insulating film formed of a single film may be disposed on the peri-contact plug 241a and the peri-wiring line 241b.

The peri-connecting structures 242a and 242b may be connected to the peri-wiring line 241b. The peri-connecting structures 242a and 242b may include a peri-connecting via 242a and a peri-connecting wiring 242b. The peri-connecting via 242a and the peri-connecting wiring 242b each include a conductive material.

Although the peri-connecting via 242a and the peri-connecting wiring 242b are shown as being different films from each other, the present disclosure is not limited thereto. Although the peri-connecting structures 242a and 242b are shown to include one peri-connecting wiring 242b disposed on one metal level, this is only for convenience of explanation, and the embodiment is not limited thereto. The peri-connecting structures 242a and 242b may include a plurality of peri-connecting wirings 242b disposed on different metal levels from each other.

A third peri-upper insulating film 265 may be disposed on the peri-connecting structures 242a and 242b. The third peri-upper insulating film 265 includes an insulating material.

The shielding conductive pattern SL and the bit line BL may be disposed on the peri-gate structure PG. The shielding conductive pattern SL and the bit line BL may be disposed on the peri-connecting structures 242a and 242b.

Unlike the shown example, the bonding insulating film 263 may not be disposed between the shielding conductive pattern SL and the peri-connecting structures 242a and 242b, and between the bit line BL and the peri-connecting structures 242a and 242b.

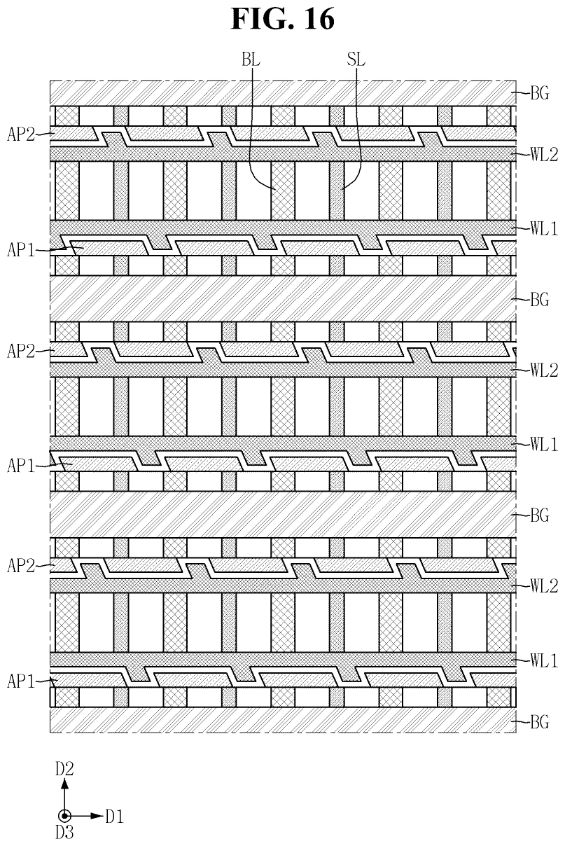

FIGS. 16 to 19 are diagrams for explaining semiconductor memory devices according to some embodiments. For convenience of explanation, points that are different from those explained using FIGS. 1 to 15 will be mainly explained.

Referring to FIG. 16, in the semiconductor memory device according to some embodiments, the first and second active patterns AP1 and AP2 may be alternately arranged in a diagonal direction with respect to the first direction D1 and the second direction D2. Here, the diagonal direction may be parallel to the upper surface of the substrate 100.

In a plan view, each of the first and second active patterns AP1 and AP2 may have a parallelogram or rhombus shape. Since the first and second active patterns AP1 and AP2 are disposed in the diagonal direction, coupling between the first and second active patterns AP1 and AP2 facing each other in the second direction D2 may be reduced.

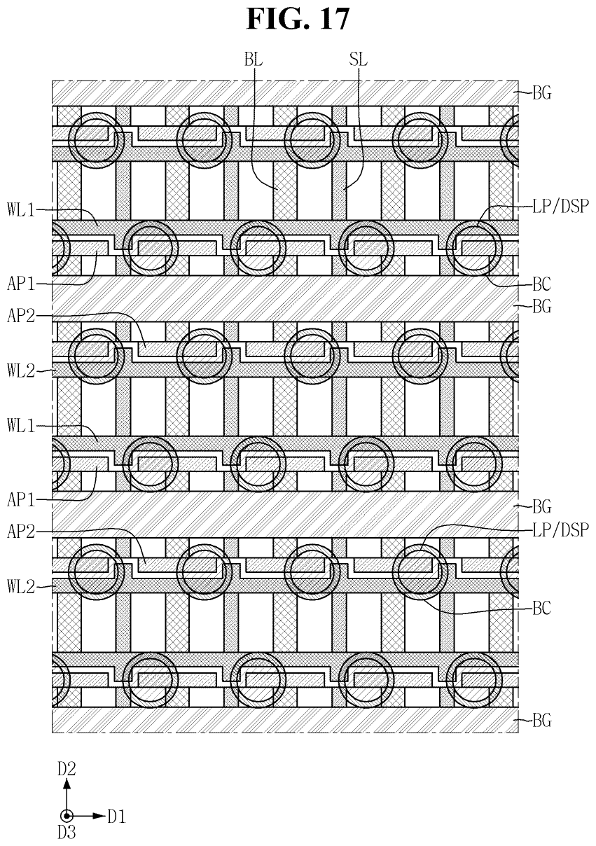

Referring to FIG. 17, in the semiconductor memory device according to some embodiments, the landing pads LP and the data storage patterns DSP may be arranged in a zigzag or honeycomb form in a plan view.

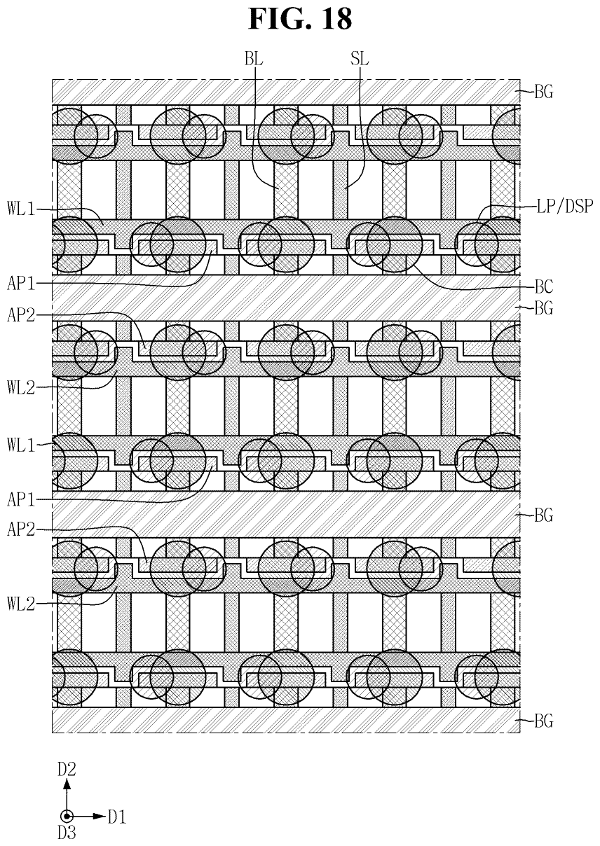

Referring to FIG. 18, in the semiconductor memory device according to some embodiments, the data storage patterns DSP may be arranged to be offset from the landing pad LP in a plan view.

Each data storage pattern DSP may be in contact with a part of the landing pad LP.

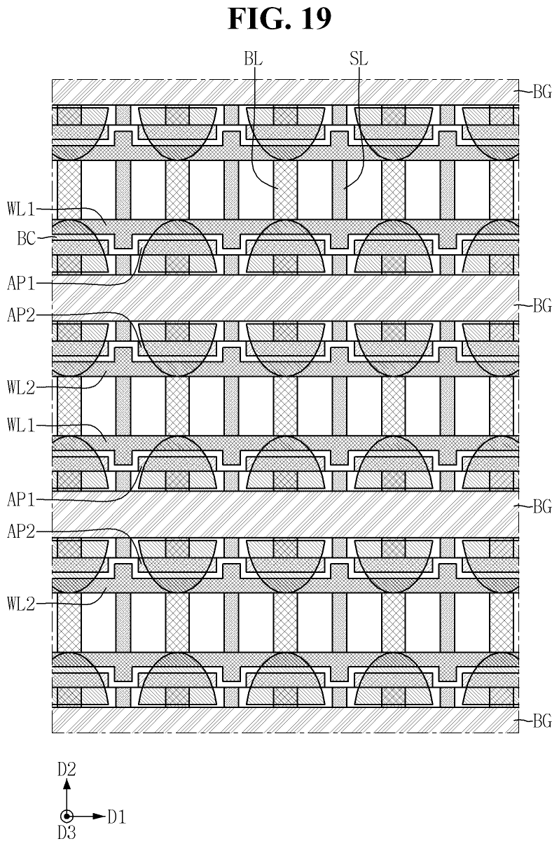

Referring to FIG. 19, in the semiconductor memory device according to some embodiments, each of the contact patterns BC disposed on the first and second active patterns AP1 and AP2 may have a semicircular shape or a semi-elliptical shape in a plan view.

The contact patterns BC may be disposed symmetrically with each other with the back gate electrode BG between them in a plan view.

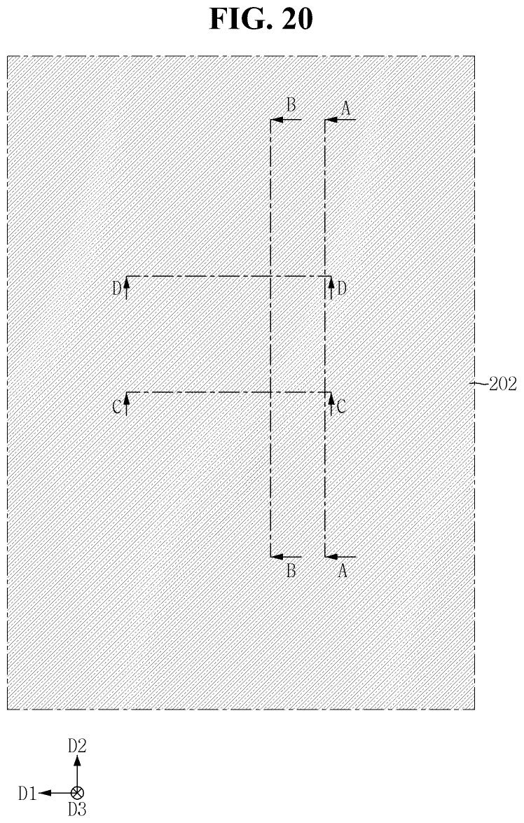

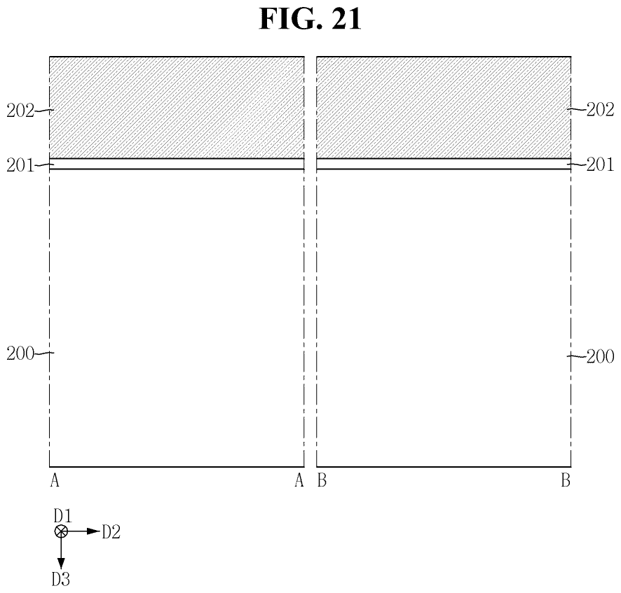

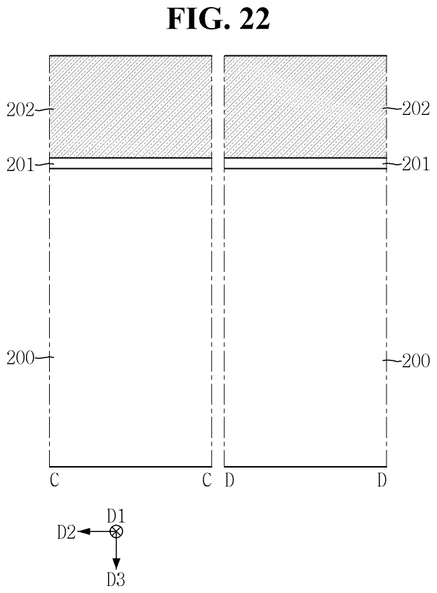

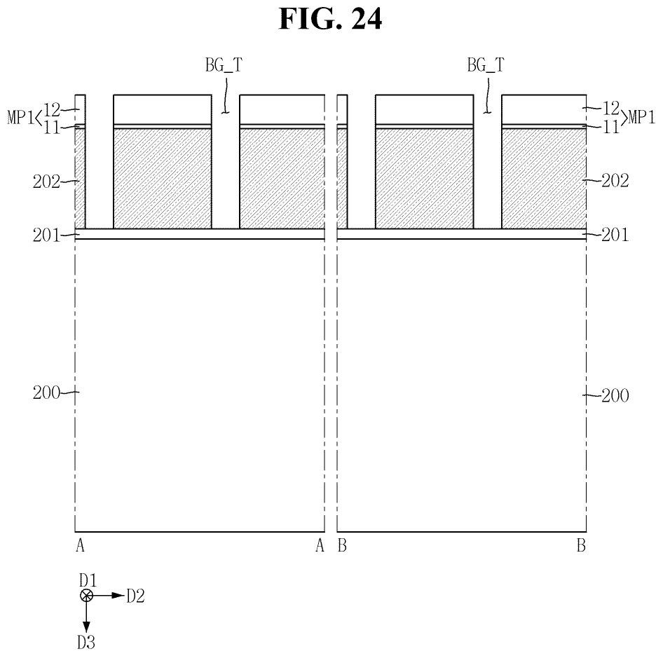

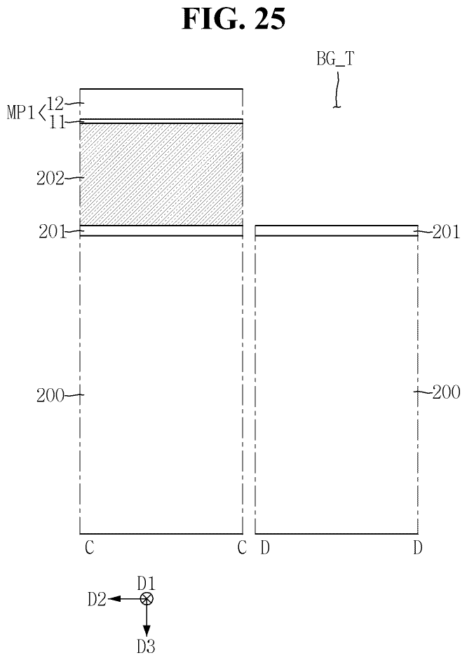

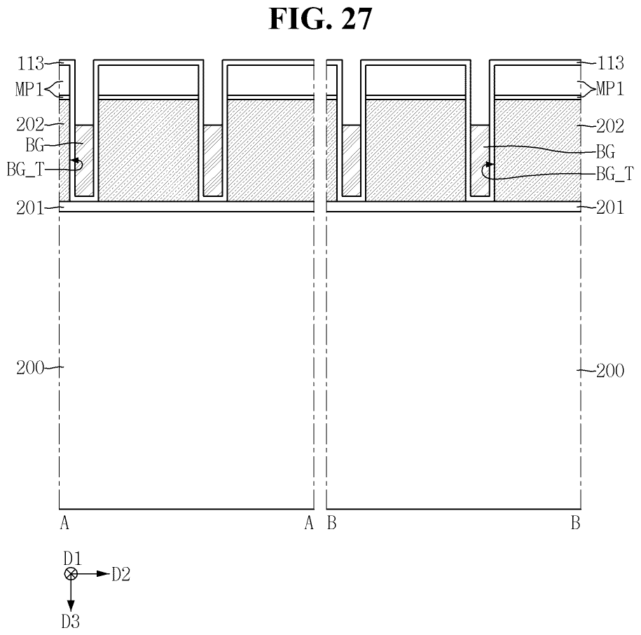

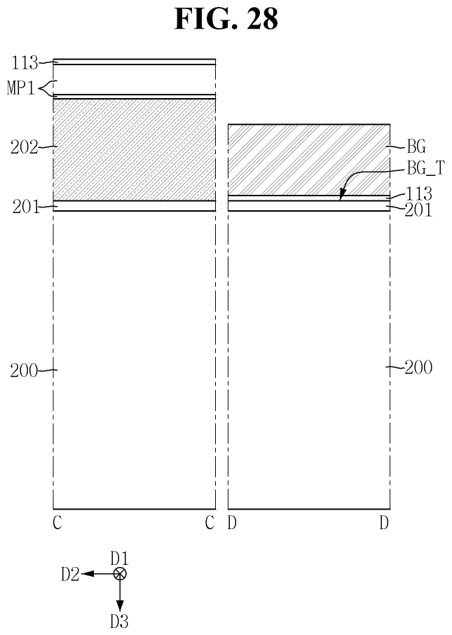

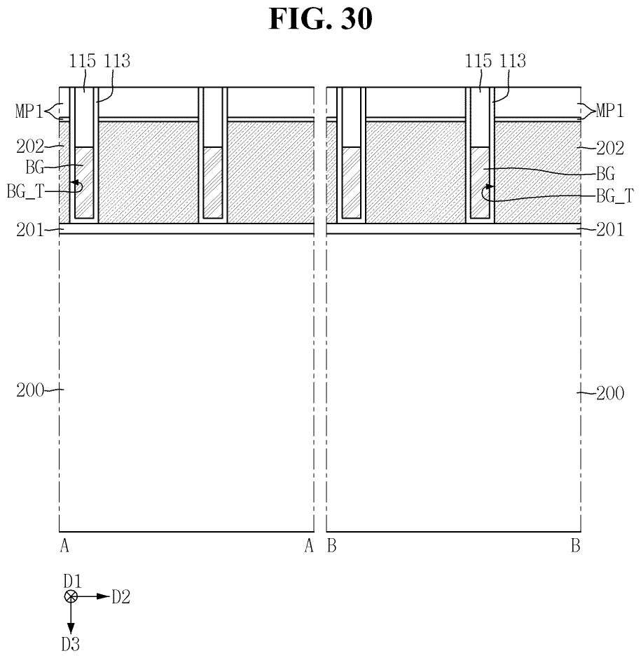

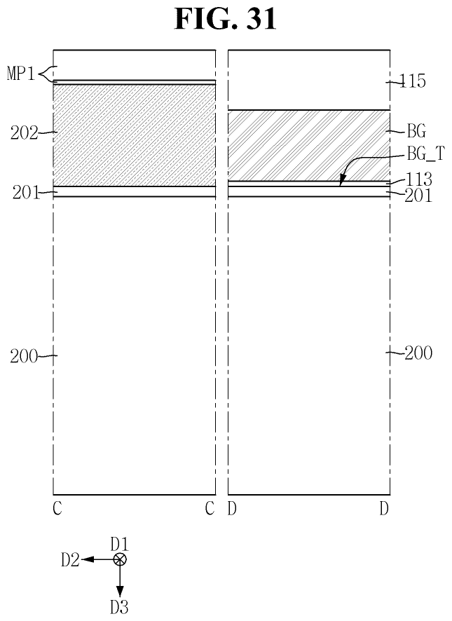

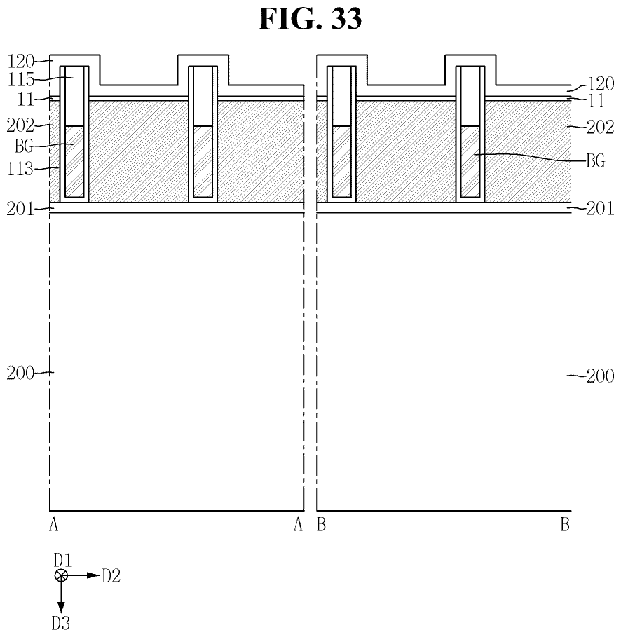

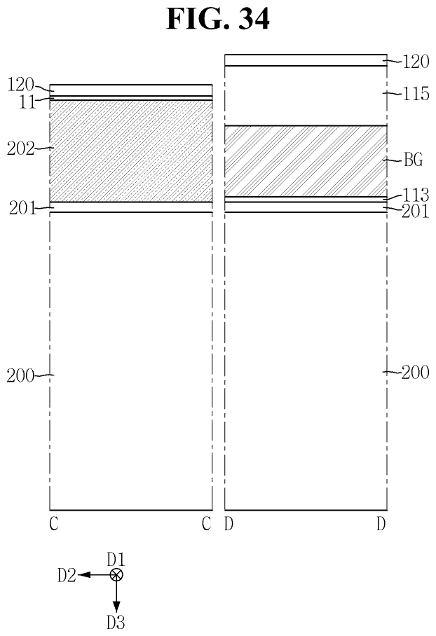

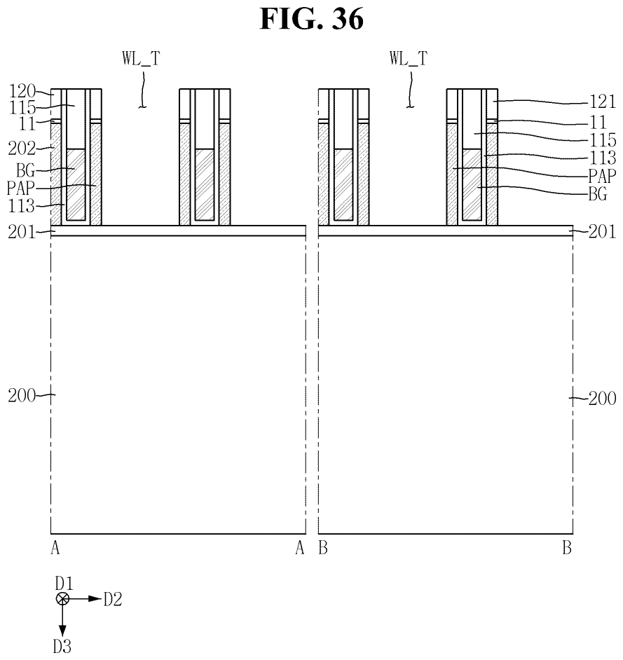

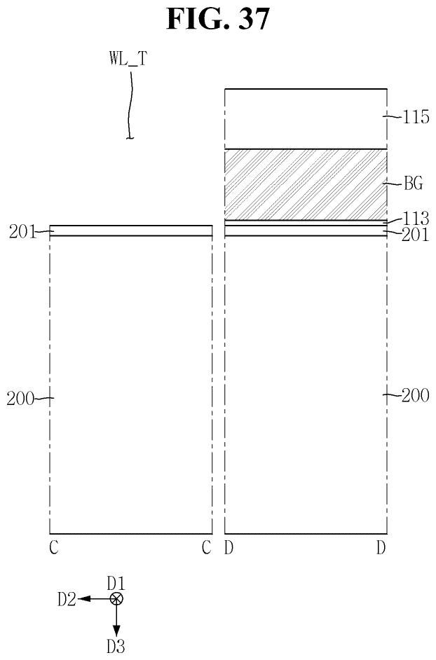

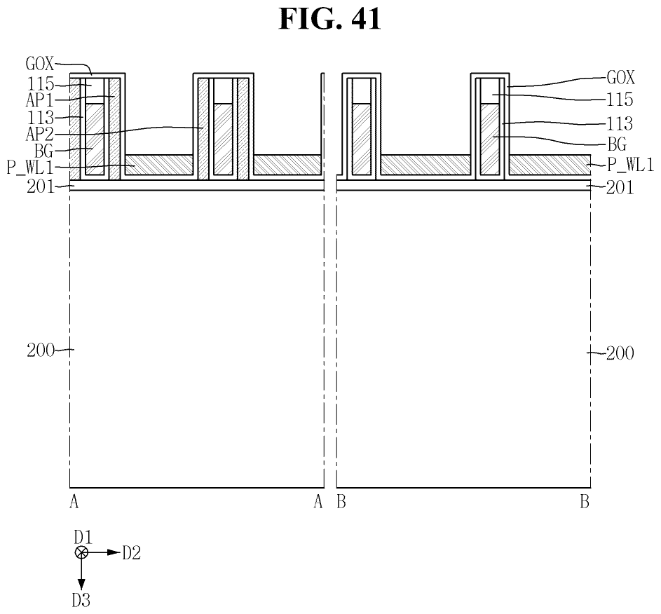

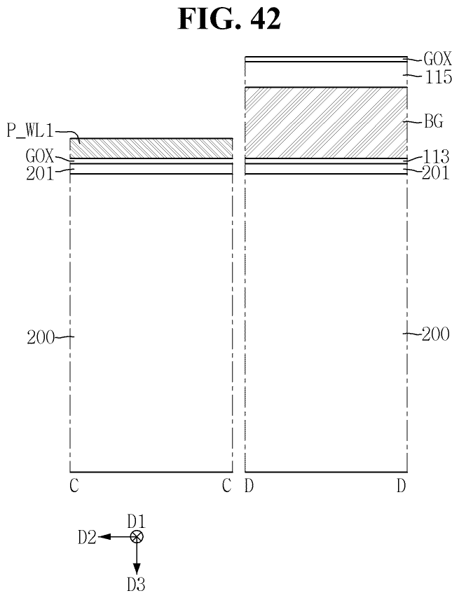

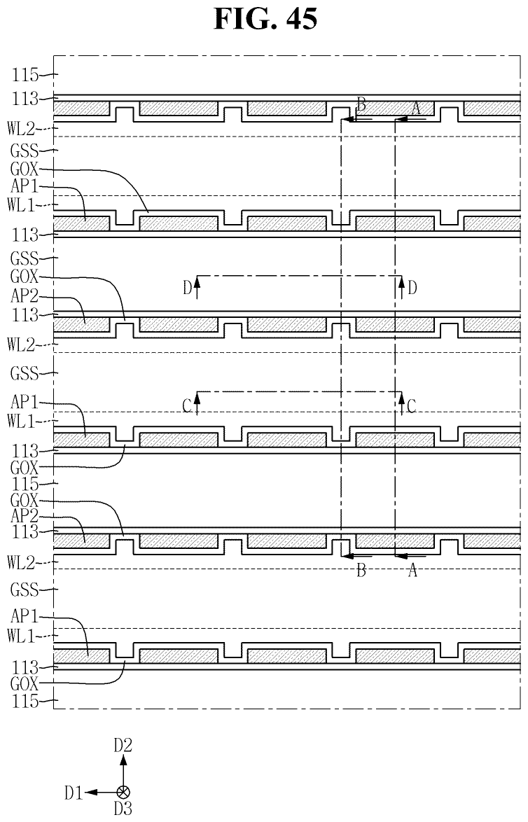

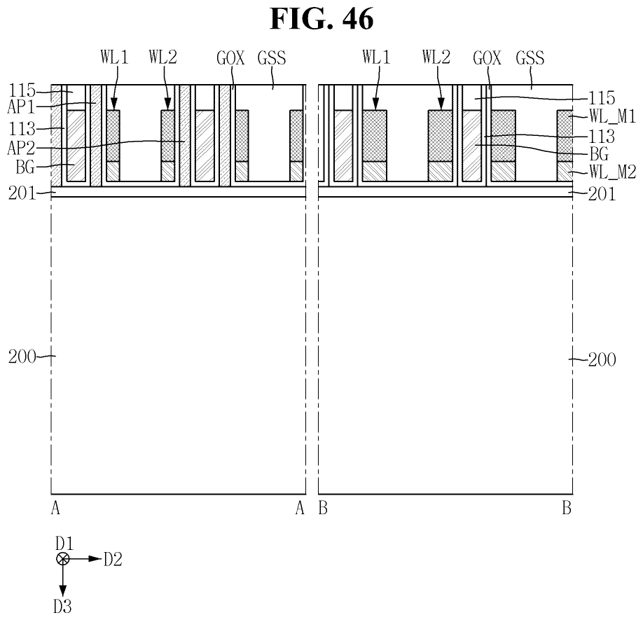

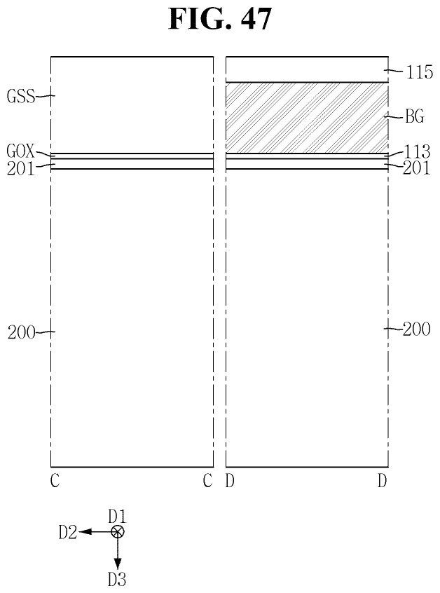

FIGS. 20 to 53 are diagrams for explaining a method for fabricating a semiconductor memory device according to some embodiments. Therefore, the semiconductor memory device described using FIGS. 14 and 15 may be fabricated.

For reference, cutting lines and coordinate systems shown in FIGS. 20 to 49 may be obtained by inverting cutting lines and coordinate systems in FIG. 1 in the first direction D1.

Referring to FIGS. 20 to 22, a sub-substrate structure including a sub-substrate 200, a buried insulating layer 201, and an active layer 202 may be provided.

The buried insulating layer 201 and the active layer 202 may be provided on the sub-substrate 200. The sub-substrate 200, the buried insulating layer 201 and the active layer 202 may be a silicon-on-insulator substrate (i.e., an SOI substrate). The sub-substrate 200 may be a semiconductor substrate. The sub-substrate 200 may be, for example, a silicon substrate, a germanium substrate, and/or a silicon-germanium substrate. In the following description, the sub-substrate 200 will be described as a silicon substrate.

The buried insulating layer 201 may be a buried oxide (BOX) formed by a SIMOX (separation by implanted oxygen) method or a bonding and layer transfer method. In contrast, the buried insulating layer 201 may be an insulating film formed by a chemical vapor deposition. The buried insulating layer 201 may include, for example, a silicon oxide film, a silicon nitride film, a silicon oxynitride film, and/or a low dielectric constant insulating film.

The active layer 202 may be a single crystal semiconductor film. The active layer 202 may be, for example, a single crystal silicon substrate, a germanium substrate, and/or a silicon-germanium substrate. The active layer 202 may have a first surface and a second surface that are opposite to each other in the third direction D3, and the second surface of the active layer 202 may be in contact with the buried insulating layer 201.

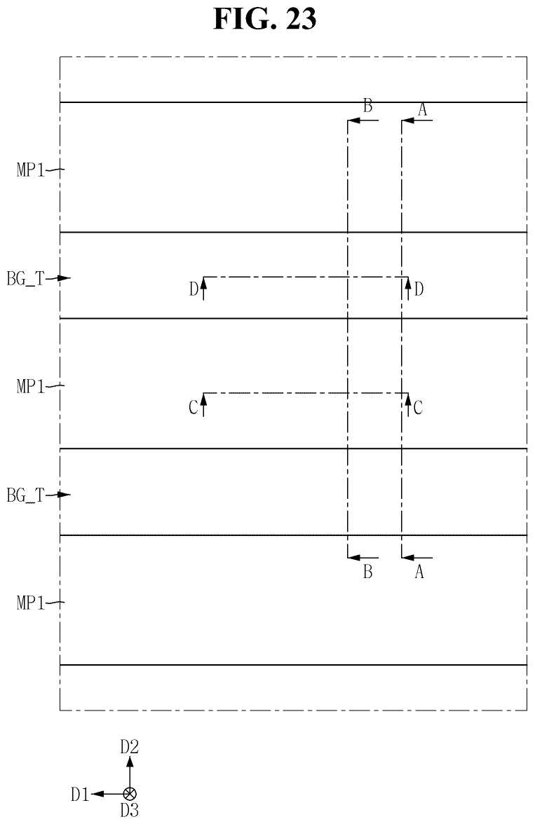

Referring to FIGS. 23 to 25, a mask pattern MP1 may be formed on the active layer 202.

The mask pattern MP1 may have linear openings extending along the first direction D1. The mask pattern MP1 may include a first lower mask film 11 and a first upper mask film 12 that are stacked in sequence. The first upper mask film 12 may be made of a material that has etching selectivity with respect to the first lower mask film 11. As an example, the first lower mask film 11 may include silicon oxide, and the first upper mask film 12 may include silicon nitride, but the embodiment is not limited thereto.

Subsequently, the active layer 202 may be anisotropically etched by using the mask pattern MP1 as an etching mask. Accordingly, the back gate trenches BG_T extending in the first direction D1 may be formed on the active layer 202. The back gate trenches BG_T may expose the buried insulating layer 201, and may be spaced apart at regular intervals in the second direction D2.

Unlike the shown example, at least a part of the buried insulating layer 201 may be removed, while the back gate trenches BG_T are being formed.

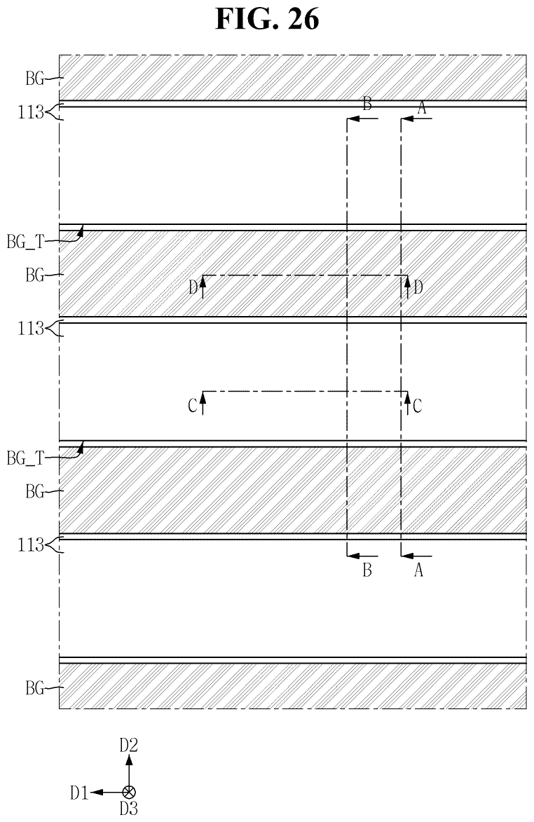

Referring to FIGS. 26 to 28, the back gate insulating pattern 113 and the back gate electrodes BG may be formed inside the back gate trench BG_T.

More specifically, the back gate insulating pattern 113 may be formed along the side wall and the bottom surface of the back gate trench BG_T and the upper surface of the mask pattern MP. The back gate conductive film may be formed on the back gate insulating pattern 113. The back gate conductive film may fill or be in the back gate trench BG_T. Subsequently, back gate electrodes BG extending in the first direction D1 may be formed, by isotropically etching the back gate conductive film. The back gate trenches BG_T may partially fill or be in the back gate trench BG_T.

Meanwhile, according to some embodiments, a gas phase doping (GPD) process or a plasma doping (PLAD) process may be performed, before forming the back gate insulating pattern 113. The active layer 202 exposed by the back gate trench BG_T may be doped with impurities through the aforementioned processes.

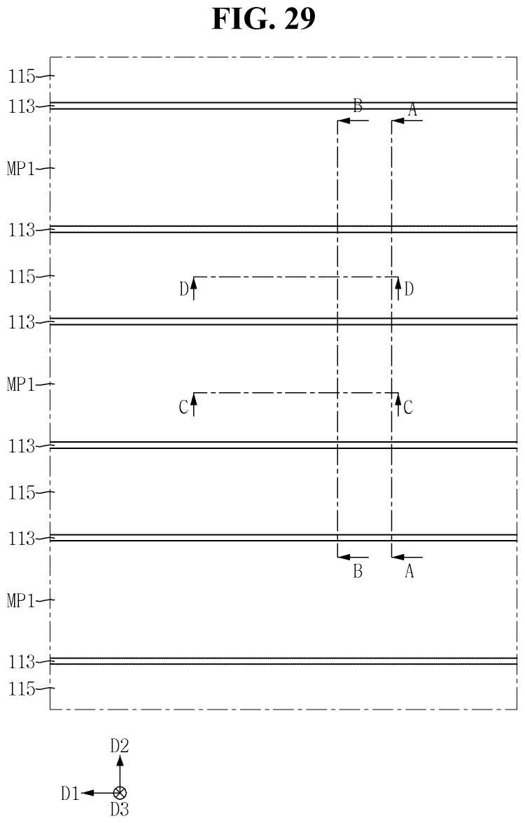

Referring to FIGS. 29 to 31, the back gate capping patterns 115 may be formed on the back gate electrode BG.

The back gate capping pattern 115 may fill or be in the remainder of the back gate trench BG_T. When the back gate capping pattern 115 and the back gate insulating pattern 113 are formed of the same material (for example, silicon oxide), the back gate insulating pattern 113 on the upper surface of the mask pattern MP may be removed, while the back gate capping pattern 115 is being formed.

Meanwhile, before forming the back gate capping patterns 115, a gas phase doping (GPD) process or a plasma doping (PLAD) process may be performed. Accordingly, the active layer 202 may be doped with impurities through the back gate trench BG_T in which the back gate electrode BG is formed.

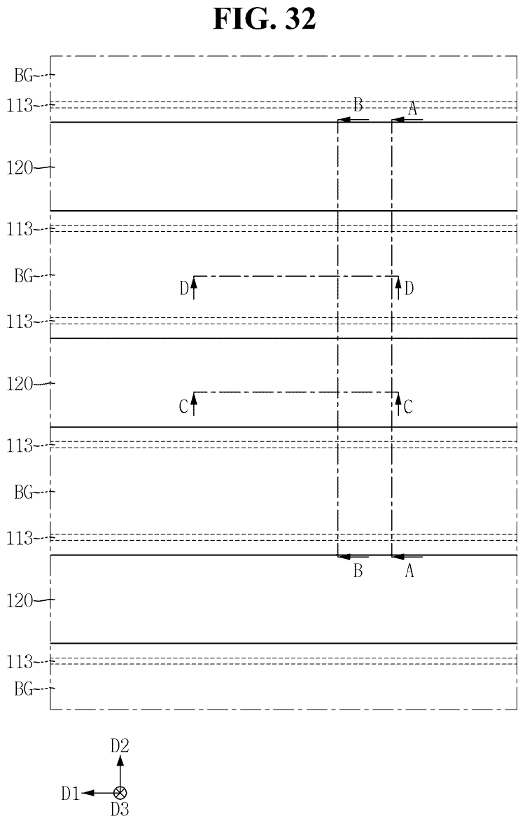

Referring to FIGS. 32 to 34, after forming the back gate capping patterns 115, the first upper mask film 12 may be removed.

The back gate capping patterns 115 may have shapes that protrude or extend above the upper surface of the first lower mask film 11.

The spacer film 120 may then be formed along the upper surface of the first lower mask film 11, the side walls of the back gate insulating patterns 113, and the upper surfaces of the back gate capping patterns 115. The spacer film 120 may be formed to have a uniform thickness. The widths of the active patterns of the vertical channel transistors may be determined depending on the deposited thickness of the spacer film 120.

The spacer film 120 may be formed of an insulating material. The spacer film 120 may include, for example, silicon oxide, silicon oxynitride, silicon nitride, silicon carbide (SiC), silicon carbon nitride (SiCN), and combinations thereof.

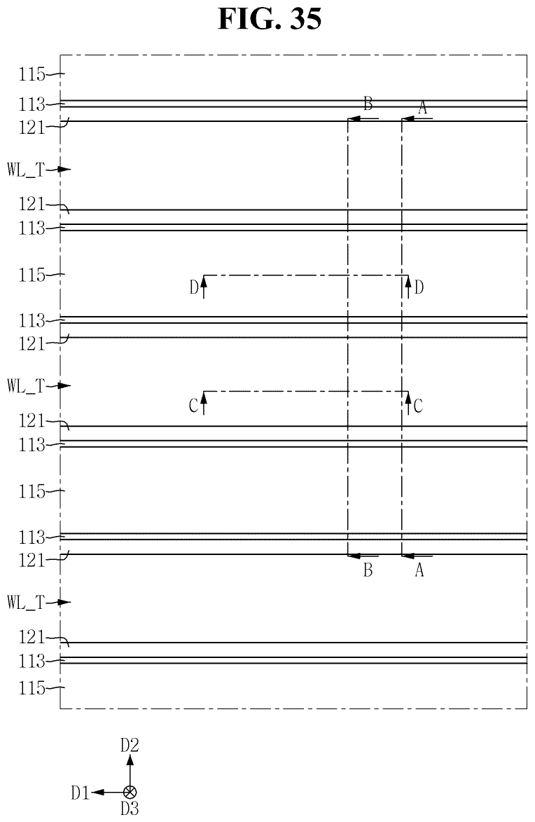

Referring to FIGS. 35 to 37, a pair of spacer patterns 121 may be formed on the side walls of the back gate insulating pattern 113, by performing an anisotropic etching process on the spacer film 120.

The anisotropic etching process may be performed on the active layer 202, by using the spacer pattern 121 as an etching mask. Accordingly, a pair of pre-active patterns PAP separated from each other may be formed on both sides of each back gate insulating pattern 113. As the pre-active patterns PAP are formed, the buried insulating layer 201 may be exposed.

The pre-active patterns PAP may extend in the first direction D1 along with the back gate electrode BG. While the pre-active patterns PAP are being formed, a word line trench WL_T may be formed between the pre-active patterns PAP adjacent to each other in the second direction D2.

Referring to FIGS. 35 to 40, a sacrificial film which fills or is in the word line trench WL_T may be formed. The mask pattern may be formed on the sacrificial film. The mask pattern may have the form of a line extending in the second direction D2. As another example, the mask pattern may have the form of a line extending in the diagonal direction with respect to the first direction D1 and the second direction D2. The sacrificial film may be etched using the mask pattern as an etch mask to form sacrificial openings inside the sacrificial film.

By etching the pre-active patterns PAP exposed to the sacrificial openings, the first active pattern AP1 and the second active pattern AP2 may be formed on both sides of the back gate electrode BG. The first active patterns AP1 may be formed on the first side wall of the back gate electrode BG to be spaced apart from each other in the first direction D1. The second active patterns AP2 may be formed on the second side wall of the back gate electrode BG to be spaced apart from each other in the first direction D1. Because the first active pattern AP1 and the second active pattern AP2 are formed, the sacrificial openings may expose a part of the back gate insulating pattern 113.

Next, the sacrificial film, the mask pattern, the spacer pattern 121, and the first lower mask film 11 may be removed. Accordingly, the first active pattern AP1 and the second active pattern AP2 may be exposed. Further, the buried insulating layer 201 may be exposed.

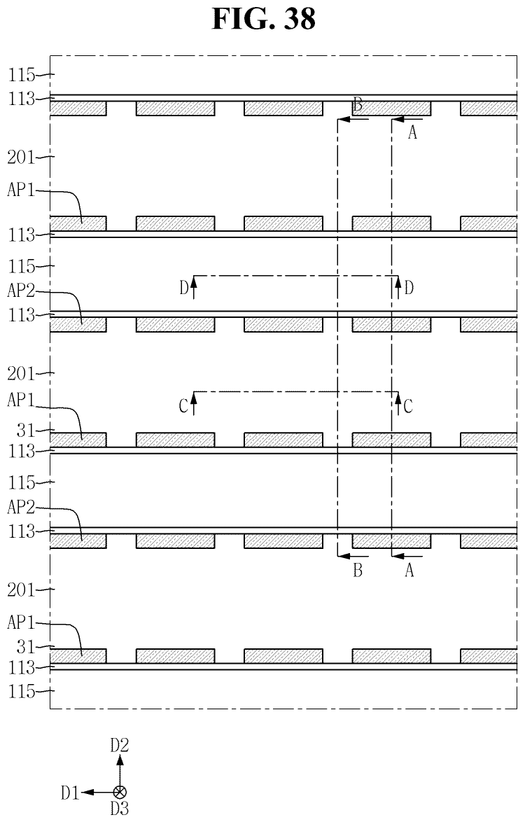

Referring to FIGS. 38 to 42, the gate insulating pattern GOX may be formed along the side walls and bottom surface of the word line trench WL_T.

The gate insulating pattern GOX may be formed along the side walls of the first active pattern AP1, the side walls of the second active pattern AP2, the upper surface of the back gate capping pattern 115, and the upper surface of the buried insulating layer 201.

The gate insulating pattern GOX may be formed, but is not limited to, by using at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) techniques.

Subsequently, a first pre-word line pattern P_WL1 may be formed on the gate insulating pattern GOX. The first pre-word line pattern P_WL1 may partially fill or be in the word line trench WL_T.

More specifically, a first pre-word line film may be formed on the gate insulating pattern GOX. The first pre-word line film may fill the word line trench WL_T. A first pre-word line pattern P_WL1 may be formed inside the word line trench WL_T by etching a part of the first pre-word line film.

The crystal direction of the conductive material crystal included in the first pre-word line pattern P_WL1 may be a random direction.

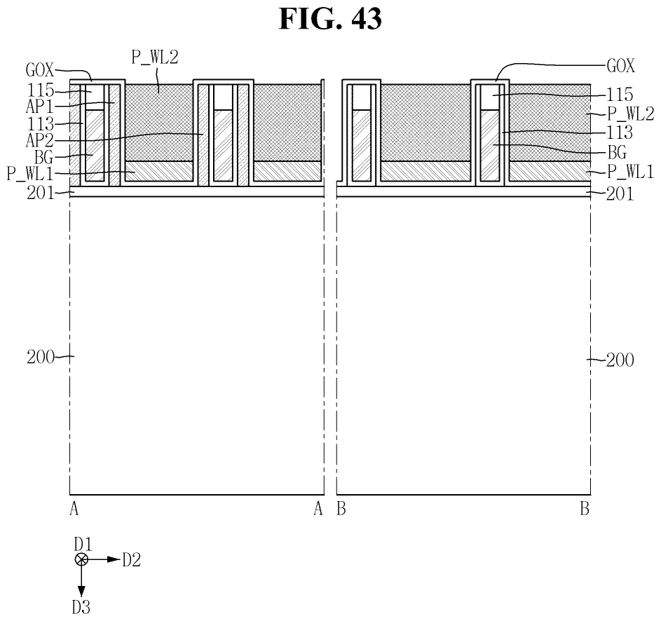

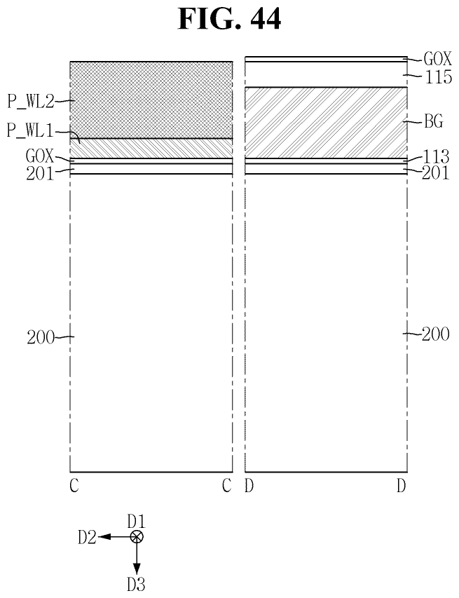

Referring to FIGS. 43 and 44, a second pre-word line pattern P_WL2 may be formed on the first pre-word line pattern P_WL1.

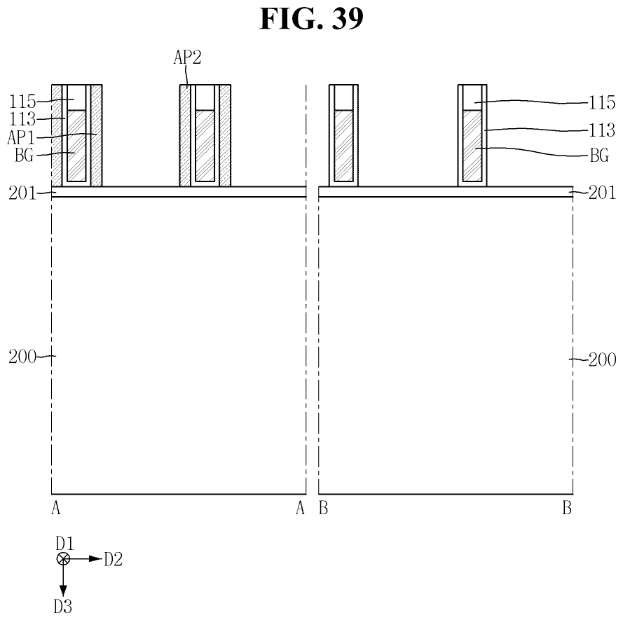

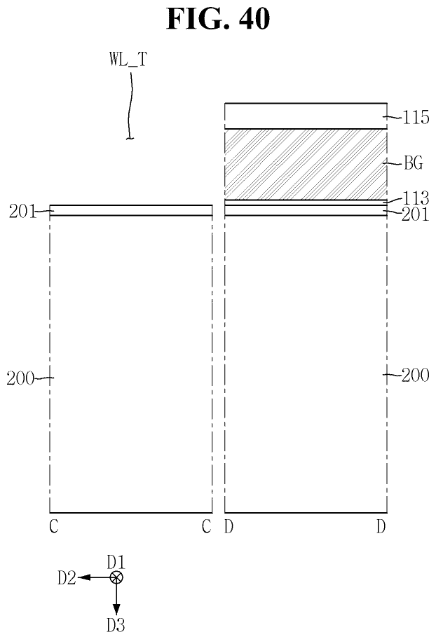

The second pre-word line pattern P_WL2 may fill or be in the word line trench (WL_T of FIGS. 39 and 40).

More specifically, the second pre-word line pattern P_WL2 may be grown in the third direction D3 above the first pre-word line pattern P_WL1. The second pre-word line pattern P_WL2 may be formed using a bottom-up growth method.

The bottom-up growth method may include, for example, a selective growth method. The selective growth method may be, for example, a method of selectively depositing a conductive material on the conductive material. The first pre-word line pattern P_WL1 may serve as a seed film for selectively growing the second pre-word line pattern P_WL2.

Since the second pre-word line pattern P_WL2 is formed by the bottom-up growth method, the crystal direction of the conductive material crystal included in the second pre-word line pattern P_WL2 may be the third direction D3.

Referring to FIGS. 43 to 47, the first word line WL1 and the second word line WL2 may be formed on the gate insulating pattern GOX, by patterning the first pre-word line pattern P_WL1 and the second pre-word line pattern P_WL2.

The first pre-word line pattern P_WL1 and the second pre-word line pattern P_WL2 may be formed using, for example, an anisotropic etching process.

The first and second word lines WL1 and WL2 may be formed on side walls of the first and second active patterns AP1 and AP2. The first pre-word line pattern P_WL1 may be patterned to form a second word line pattern WL_M2. The second pre-word line pattern P_WL2 may be patterned to form a first word line pattern WL_M1.

Depending on the method of patterning the first pre-word line pattern P_WL1 and the second pre-word line pattern P_WL2, the width of the first word line WL1 in the second direction D2 may be the same as or different from the width of the second word line WL2 in the second direction D2.

At the time of the anisotropic etching process on the first pre-word line pattern P_WL1 and the second pre-word line pattern P_WL2, the gate insulating pattern GOX may be used as an etching stop film. Unlike the shown example, the gate insulating pattern GOX may be over-etched to expose the buried insulating layer 201. The first and second word lines WL1 and WL2 may have various shapes depending on the anisotropic etching process on the first pre-word line pattern P_WL1 and the second pre-word line pattern P_WL2.

The upper surface of the first word line WL1 and the upper surface of the second word line WL2 may be located at a lower level than the upper surfaces of the first and second active patterns AP1 and AP2.

As an example, after forming the first and second word lines WL1 and WL2, a gas phase doping (GPD) process or a plasma doping (PLAD) process may be performed. Accordingly, impurities may be doped into the first and second active patterns AP1 and AP2 through the gate insulating pattern GOX exposed by the first and second word lines WL1 and WL2.

Subsequently, a gate separation pattern GSS may be formed on the first word line WL1 and the second word line WL2. For example, an upper surface of the gate separation pattern GSS may be disposed on the same plane as the upper surface of the back gate capping pattern 115.

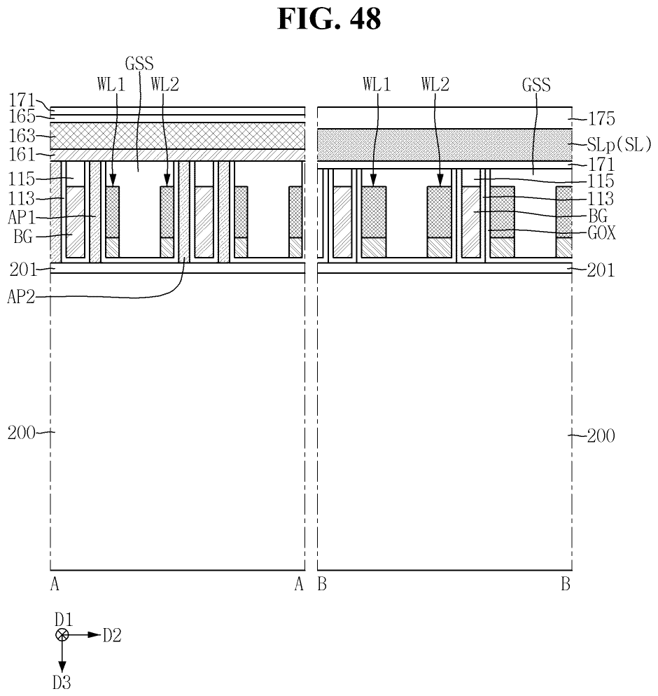

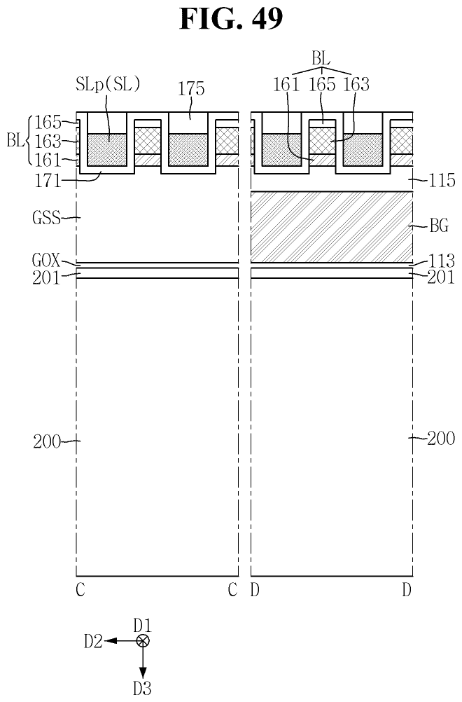

Referring to FIGS. 48 and 49, bit lines BL extending in the second direction D2 may be formed on the gate separation pattern GSS and the back gate capping pattern 115.

The bit line BL may include a bit line mask pattern 165, a metal pattern 163, and a semiconductor pattern 161. During the formation of the bit line BL, a part of the back gate capping pattern 115 and a part of the gate separation pattern GSS may be etched.

Subsequently, a shielding conductive pattern SL may be formed between the bit lines BL adjacent in the first direction D1.

More specifically, the shielding insulating liner 171 may be formed along the profile of the bit line BL. The shielding insulating liner 171 may define a shielding region between the bit lines BL adjacent in the first direction D1. The shielding conductive film may be formed on the shielding insulating liner 171. The shielding conductive film may fill or be in the shielding region defined by the shielding insulating liner 171. At least a part of the shielding conductive film may be recessed to form the shielding conductive pattern SL. As an example, when the shielding conductive film formed on the bit line BL is completely removed, the shielding conductive pattern SL may include a plurality of linear shielding conductive line patterns SLp. As another example, when a part or all of the shielding conductive film formed on the bit line BL is not removed, the shielding conductive pattern SL may include a shielding conductive plate (SLh of FIGS. 12 and 13) having a flat plate shape, and a plurality of shielding conductive line patterns SLp having a line shape. A shielding insulating capping film 175 may be formed on the shielding conductive pattern SL.

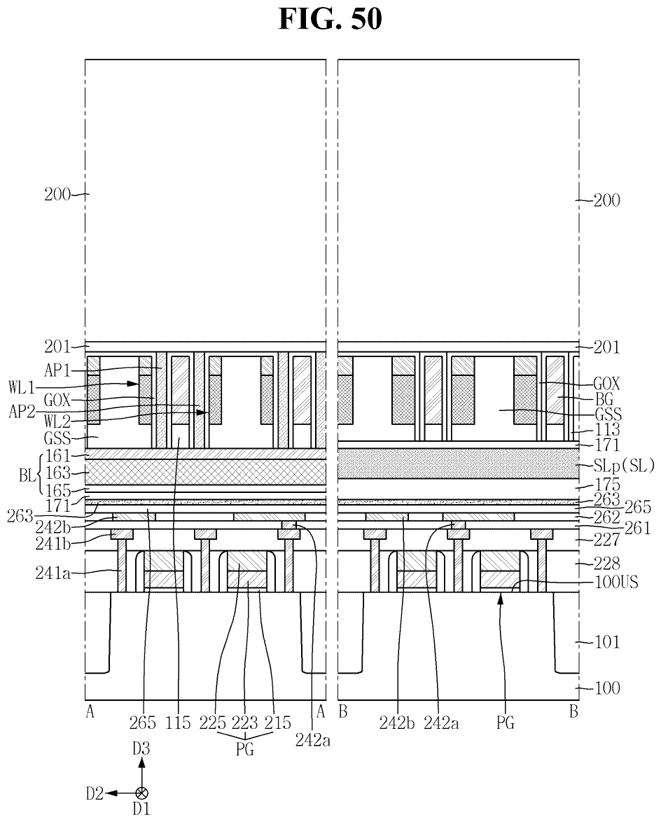

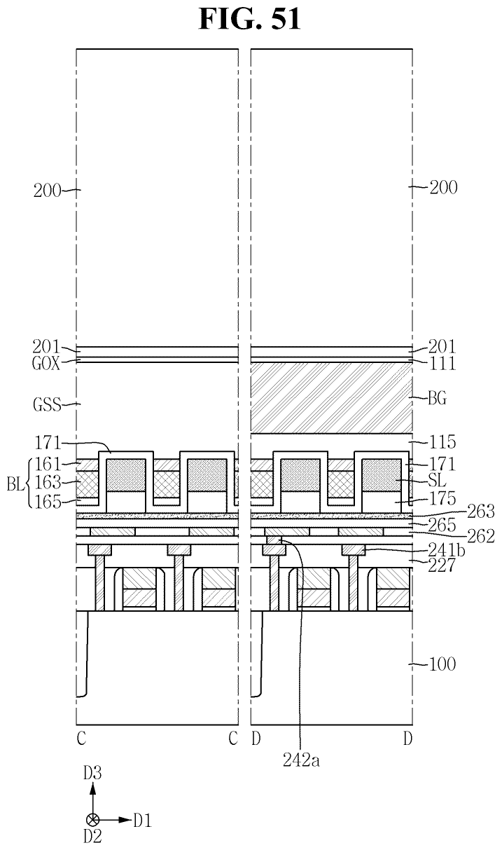

Referring to FIGS. 50 and 51, a peri-gate structure PG may be formed on the substrate 100.

A sub-substrate 200 on which the back gate electrodes BG, the word lines WL1 and WL2, the active patterns AP1 and AP2, the bit lines BL and the shielding conductive patterns SL are formed may be combined with the substrate 100. The substrate 100 and the sub-substrate 200 may be bonded such that the bit line BL and the peri-gate structure PG face each other.

The substrate 100 and the sub-substrate 200 may be bonded using the bonding insulating film 263. Unlike the shown example, the substrate 100 and the sub-substrate 200 may be bonded without the bonding insulating film 263.

Unlike the shown example, the sub-substrate 200 on which the back gate electrodes BG, the word lines WL1 and WL2, the active patterns AP1 and AP2, the bit lines BL and the shielding conductive patterns SL are formed may be bonded with the substrate 100 on which no peri-gate structure PG is formed.

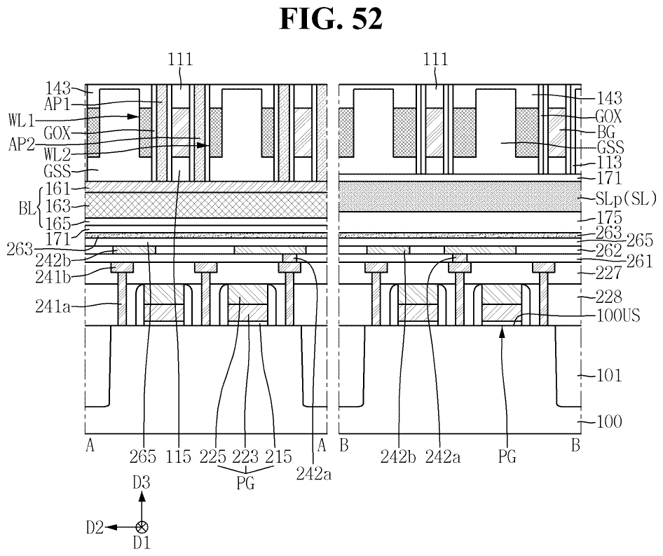

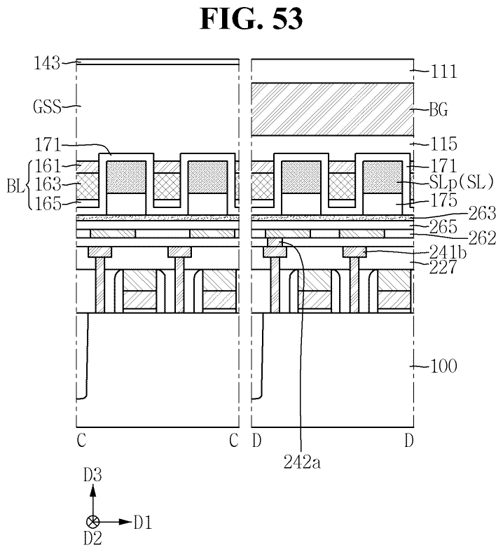

Referring to FIGS. 52 and 53, after bonding the substrate 100 and the sub-substrate 200, a back lapping process for removing the sub-substrate 200 may be performed.

Removal of the sub-substrate 200 may include exposing the buried insulating layer 201 by sequentially performing a grinding process and a wet etching process.

Next, the buried insulating layer 201 may be removed to expose the first active pattern AP1 and the second active pattern AP2.

When the buried insulating layer 201 is removed, a part of the gate insulating pattern GOX and a part of the back gate insulating pattern 113 may be exposed.

Thereafter, the exposed gate insulating pattern GOX and the exposed back gate insulating pattern 113 may be removed. Therefore, the back gate electrode BG, the first word line WL1, and the second word line WL2 may be exposed.

An etch-back process may then be performed to remove at least a part of the second word line pattern WL_M2. A gate capping pattern 143 may be formed on the recessed first and second word lines WL1 and WL2.

While at least a part of the second word line pattern WL_M2 is being removed, a part of the back gate electrode BG may also be removed.

Next, referring to FIGS. 2, 3, 14, and 15, contact holes for exposing the first active pattern AP1 and the second active pattern AP2 may be formed inside the contact etching stop film 212 and the contact interlayer insulating film 231. The contact pattern BC may be formed inside the contact hole. The contact patterns BC may be formed on the first active pattern AP1 and the second active pattern AP2. The contact patterns BC may be connected to the first active pattern AP1 and the second active pattern AP2. The data storage patterns DSP may be formed on the contact pattern BC.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor memory device comprising:
a bit line that extends in a first direction and is on a substrate;
an active pattern on the bit line, wherein the active pattern comprises a first side wall and a second side wall that are opposite to each other in the first direction, wherein the active pattern comprises a first surface and a second surface that are opposite to each other in a second direction that is perpendicular to the first direction, and wherein the first surface of the active pattern is electrically connected to the bit line;
a word line that is on the first side wall of the active pattern and extends in a third direction that intersects the first direction; and
a data storage pattern that is on the active pattern and is electrically connected to the second surface of the active pattern,
wherein the word line comprises a first surface and a second surface that are opposite to each other in the second direction,
wherein the word line comprises a first line pattern comprising a plurality of first conductive material crystals,
wherein a direction in which a crystal lattice of each of the plurality of first conductive material crystals extends is substantially the same as the second direction, and
wherein at least one of the first surface of the word line or the second surface of the word line comprises at least one of the plurality of first conductive material crystals.

2. The semiconductor memory device of claim 1, wherein the first surface of the word line and the second surface of the word line comprises the at least one of the plurality of first conductive material crystals.

3. The semiconductor memory device of claim 2, wherein the at least one of the plurality of first conductive material crystals extends from the first surface of the word line to the second surface of the word line.

4. The semiconductor memory device of claim 1, wherein:
the word line comprises a second line pattern comprising a plurality of second conductive material crystals,
the first surface of the word line comprises the at least one of the plurality of first conductive material crystals, and
the second surface of the word line comprises at least one of the plurality of second conductive material crystals.

5. The semiconductor memory device of claim 4, wherein:
the plurality of first conductive material crystals has a first average grain size in the second direction,
the plurality of second conductive material crystals has a second average grain size in the second direction, and
the first average grain size is greater than or equal to three times the second average grain size.

6. The semiconductor memory device of claim 4, wherein the at least one of the first conductive material crystals and the at least one of the second conductive material crystals comprise a same conductive material.

7. The semiconductor memory device of claim 1, further comprising:
a back gate electrode that is on the second side wall of the active pattern and extends in the third direction,
wherein the active pattern is between the back gate electrode and the word line.

8. The semiconductor memory device of claim 1, further comprising:
a shielding conductive pattern on the substrate,
wherein the shielding conductive pattern comprises a shielding conductive plate and a plurality of shielding conductive line patterns that extend from the shielding conductive plate,
wherein each of the plurality of shielding conductive line patterns extends in the first direction, and
wherein the bit line is between adjacent ones of the shielding conductive line patterns.

9. The semiconductor memory device of claim 1, further comprising:
a shielding conductive pattern that is adjacent to the bit line and extends in the first direction,
wherein the bit line comprises an upper surface and a bottom surface that are opposite to each other in the second direction,
wherein the upper surface of the bit line faces the active pattern, and
wherein the shielding conductive pattern is not on the bottom surface of the bit line.

10. The semiconductor memory device of claim 1, wherein:
the word line comprises a first portion and a second portion that are spaced apart from each other in the third direction, and
a width of the first portion of the word line in the first direction is less than a width of the second portion of the word line in the first direction.

11. A semiconductor memory device comprising:
a bit line that extends in a first direction and is on a substrate;
a first active pattern on the bit line;
a second active pattern that is on the bit line and spaced apart from the first active pattern in the first direction;
a first word line that is between the first active pattern and the second active pattern and extends in a second direction that intersects the first direction;
a second word line that is between the first active pattern and the second active pattern, extends in the second direction, and is spaced apart from the first word line in the first direction;
a gate separation pattern that is on the bit line and comprises a horizontal portion and a protruding portion, wherein the horizontal portion of the gate separation pattern is between the first word line and the bit line and between the second word line and the bit line, wherein the protruding portion of the gate separation pattern is between the first word line and the second word line, and wherein a width of the horizontal portion of the gate separation pattern in the first direction is greater than a width of the protruding portion of the gate separation pattern in the first direction; and
a data storage pattern that is electrically connected to the first active pattern and the second active pattern,
wherein the first word line comprises a first plurality of conductive material crystals and the second word line each comprises a second plurality of conductive material crystals,
wherein the first plurality of conductive material crystals comprises a first conductive material crystal, and
wherein a height of the first conductive material crystal in a third direction that is perpendicular to the first direction and the second direction is equal to a height of the first word line in the third direction.

12. The semiconductor memory device of claim 11, wherein:
the first plurality of conductive material crystals comprises a second conductive material crystal, and
a height of the second conductive material crystal in the third direction is less than the height of the first conductive material crystal in the third direction.

13. The semiconductor memory device of claim 12, wherein a direction in which a crystal lattice of each of the first conductive material crystal and a the second conductive material crystal extends is substantially the same as the third direction.

14. The semiconductor memory device of claim 11, further comprising a back gate electrode that is on the bit line, is spaced apart from the first word line and the second word line in the first direction, and extends in the second direction.

15. The semiconductor memory device of claim 11, wherein a width of the first word line in the first direction is equal to a width of the second word line in the first direction.

16. The semiconductor memory device of claim 11, wherein a width of the first word line in the first direction is greater than a width of the second word line in the first direction.

17. The semiconductor memory device of claim 11, further comprising a shielding conductive pattern that is adjacent to the bit line in the second direction and comprises a plurality of shielding conductive line patterns that extend in the first direction.

18. A semiconductor memory device comprising:
a peri-gate structure on a substrate;
a bit line that extends in a first direction and is on the peri-gate structure;
a shielding conductive pattern that is on the peri-gate structure and comprises a plurality of shielding conductive line patterns that extend in the first direction and are adjacent to the bit line;
a first word line that is on the bit line and the shielding conductive pattern and extends in a second direction that intersects the first direction;
a second word line that is on the bit line and the shielding conductive pattern, extends in the second direction, and is spaced apart from the first word line in the first direction;
a back gate electrode that is between the first word line and the second word line and extends in the second direction;
a first active pattern that is on the bit line and is between the first word line and the back gate electrode;
a second active pattern that is on the bit line and is between the first word line and the back gate electrode; and
a data storage pattern that is electrically connected to the first active pattern and the second active pattern,
wherein the first word line and the second word line each comprise a plurality of conductive material crystals that each have a crystal lattice that extends in a direction that is substantially the same as a third direction that is perpendicular to the first direction and the second direction,
wherein the first word line comprises a first surface and a second surface that are opposite to each other in the third direction,
wherein the second word line comprises a first surface and a second surface that are opposite to each other in the third direction,
wherein a first set of the plurality of conductive material crystals comprise the first surface of the first word line and the second surface of the first word line, and
wherein a second set of the plurality of conductive material crystals define the first surface of the second word line and the second surface of the second word line.

19. The semiconductor memory device of claim 18, wherein:
the plurality of conductive material crystals comprise a first conductive material crystal, and
a height of the first conductive material crystal in the third direction is equal to a height of the first word line in the third direction and a height of the second word line in the third direction.

20. The semiconductor memory device of claim 18, wherein:
the shielding conductive pattern further comprises a shielding conductive plate,
the shielding conductive line pattern extends from the shielding conductive plate in the third direction, and
the bit line is on the shielding conductive plate.
